(19) United States
(12) Patent Application Publication
(10) Pub. No.: US 2026/0123148 A1
(43) Pub. Date: Apr. 30, 2026

(54) DISPLAY DEVICE

(71) Applicant: LG Display Co., Ltd., Seoul (KR)

(72) Inventors: Hanchul PARK, Goyang-si (KR); JinYeong KIM, Goyang-si (KR); WonJun CHOI, Paju-si (KR)

(73) Assignee: LG Display Co., Ltd., Seoul (KR)

(21) Appl. No.: 19/003,293

(22) Filed: Dec. 27, 2024

(30) Foreign Application Priority Data
Feb. 27, 2024 (KR) 10-2024-0028219

(51) Int. Cl. H10H 29/80; H10H 29/49

(52) U.S. Cl. CPC H10H 29/8321; H10H 29/49

(57) ABSTRACT

A display device includes a first substrate including a plurality of top pads; a second substrate including a plurality of bottom pads; and a plurality of side lines which connects the plurality of top pads and the plurality of bottom pads, wherein each of the plurality of bottom pads includes a first bottom pad electrode disposed below the second substrate; a first insulating layer disposed below the first bottom pad electrode; a second bottom pad electrode disposed below the first insulating layer; a third bottom pad electrode disposed below the second bottom pad electrode; and a second insulating layer disposed below the third bottom pad electrode, and the third bottom pad electrode is formed of a transparent conductive material. Therefore, manufacturing process and manufacturing cost of the display device may be reduced.

### CROSS-REFERENCE TO RELATED APPLICATIONS

This application claims the priority of Korean Patent Application No. 10-2024-0028219 filed on Feb. 27, 2024, in the Korean Intellectual Property Office, the disclosure of which is incorporated herein by reference.

### BACKGROUND

### Technical Field

The present disclosure relates to a display device, and more particularly, to a display device using a light emitting diode (LED).

### Discussion of the Related Art

As display devices which are used for a monitor of a computer, a television, a cellular phone, or the like, there are an organic light emitting display (OLED) device which is a self-emitting device, a liquid crystal display (LCD) device which requires a separate light source, and the like.

An applicable range of the display device is diversified to personal digital assistants as well as monitors of computers and televisions and a display device with a large display area and a reduced volume and weight is being studied.

Further, recently, a display device including a light emitting diode (LED) is attracting attention as a next generation display device. Since the LED is formed of an inorganic material, rather than an organic material, reliability is excellent so that a lifespan thereof is longer than that of the liquid crystal display device or the organic light emitting display device. Further, the LED has a fast lighting speed, excellent luminous efficiency, and a strong impact resistance so that a stability is excellent and an image having a high luminance can be displayed.

### SUMMARY

Accordingly, embodiments of the present disclosure are directed to a display device that substantially obviates one or more of the problems due to limitations and disadvantages of the related art.

An aspect of the present disclosure is to provide a display device with a reduced manufacturing process and a reduced manufacturing cost.

Another aspect of the present disclosure is to provide a display device in which a short-circuit path is reduced to reduce a defect problem.

Still another aspect of the present disclosure is to provide a display device with a reduced parasitic capacitor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display device comprises a first substrate including a plurality of top pads; a second substrate including a plurality of bottom pads; and a plurality of side lines which connects the plurality of top pads and the plurality of bottom pads, wherein each of the plurality of bottom pads includes a first bottom pad electrode disposed below the second substrate; a first insulating layer disposed below the first bottom pad electrode; a second bottom pad electrode disposed below the first insulating layer; a third bottom pad electrode disposed below the second bottom pad electrode; and a second insulating layer disposed below the third bottom pad electrode, and the third bottom pad electrode is formed of a transparent conductive material.

Other detailed matters of the exemplary embodiments are included in the detailed description and the drawings.

According to the present disclosure, a mask process is reduced to reduce a manufacturing cost of the display device.

According to the present disclosure, a structure of a pad unit is improved to suppress a defect problem.

According to the present disclosure, corrosion of the pad unit is suppressed to improve the reliability of the pad unit.

It is to be understood that both the foregoing general description and the following detailed description are exemplary and explanatory and are intended to provide further explanation of the inventive concepts as claimed.

### BRIEF DESCRIPTION OF DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic diagram of a display device according to an exemplary embodiment of the present disclosure;

FIG. 2A is a partial cross-sectional view of a display device according to an exemplary embodiment of the present disclosure;

FIG. 2B is a perspective view of a tiling display device according to an exemplary embodiment of the present disclosure;

FIG. 3 is an enlarged plan view of a first substrate of a display device according to an exemplary embodiment of the present disclosure;

FIG. 4 is an enlarged plan view of a second substrate of a display device according to an exemplary embodiment of the present disclosure;

FIG. 5 is a cross-sectional view of a sub pixel of a display device according to an exemplary embodiment of the present disclosure;

FIG. 6 is a cross-sectional view of a pad area of a display device according to an exemplary embodiment of the present disclosure;

FIG. 7A is a cross-sectional view of a top pad of a display device according to an exemplary embodiment of the present disclosure;

FIG. 7B is a cross-sectional view of a bottom pad of a display device according to an exemplary embodiment of the present disclosure;

FIG. 8 is a cross-sectional view of a second substrate taken along line A-A′ of FIG. 4; and

FIG. 9 is a cross-sectional view of a second substrate taken along line B-B′ of FIG. 4.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately”or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

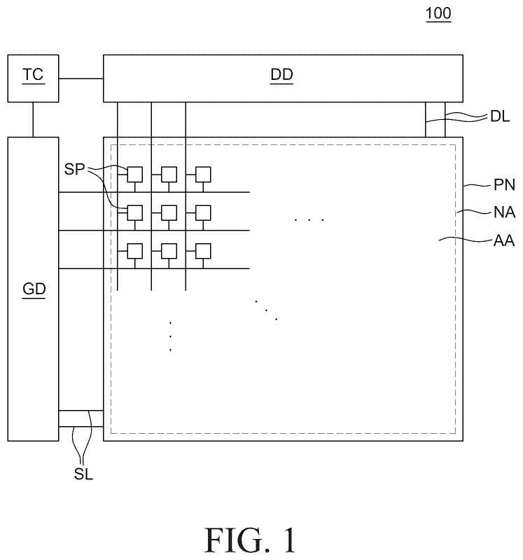

FIG. 1 is a schematic diagram of a display device according to an exemplary embodiment of the present disclosure. In FIG. 1, for the convenience of description, among various components of the display device 100, only a display panel PN, a gate driver GD, a data driver DD, and a timing controller TC are illustrated.

Referring to FIG. 1, the display device 100 includes a display panel PN including a plurality of sub pixels SP, a gate driver GD and a data driver DD which supply various signals to the display panel PN, and a timing controller TC which controls the gate driver GD and the data driver DD.

The gate driver GD supplies a plurality of scan signals to a plurality of scan lines SL according to a plurality of gate control signals supplied from the timing controller TC. Even though in FIG. 1, it is illustrated that one gate driver GD is disposed to be spaced apart from one side of the display panel PN, the number of the gate drivers GD and the placement thereof are not limited thereto.

The data driver DD converts image data input from the timing controller TC into a data voltage using a reference gamma voltage in accordance with a plurality of data control signals supplied from the timing controller TC. The data driver DD may supply the converted data voltage to the plurality of data lines DL.

The timing controller TC aligns image data input from the outside to supply the image data to the data driver DD. The timing controller TC may generate a gate control signal and a data control signal using synchronization signals input from the outside, such as a dot clock signal, a data enable signal, and horizontal/vertical synchronization signals. The timing controller TC supplies the generated gate control signal and data control signal to the gate driver GD and the data driver DD, respectively, to control the gate driver GD and the data driver DD.

The display panel PN is a configuration which displays images to the user and includes the plurality of sub pixels SP. In the display panel PN, the plurality of scan lines SL and the plurality of data lines DL intersect each other and the plurality of sub pixels SP is connected to the scan lines SL and the data lines DL, respectively. In addition, even though it is not illustrated in the drawing, each of the plurality of sub pixels SP may be connected to a high potential power line, a low potential power line, a reference line, and the like.

In the display panel PN, an active area AA and a non-active area NA enclosing the active area AA may be defined.

The active area AA is an area in which images are displayed in the display device 100. In the active area AA, a plurality of sub pixels SP which configures a plurality of pixels PX and a circuit for driving the plurality of sub pixels SP may be disposed. The plurality of sub pixels SP is a minimum unit which configures the active area AA and n sub pixels SP may form one pixel PX. In each of the plurality of sub pixels SP, a light emitting diode, a thin film transistor, and the like for driving the light emitting diode may be disposed. The plurality of light emitting diodes may be defined in different manners depending on the type of the display panel PN. For example, when the display panel PN is an inorganic light emitting display panel, the light emitting diode may be a light emitting diode (LED) or a micro light emitting diode (LED).

In the active area AA, a plurality of signal lines which transmits various signals to the plurality of sub pixels SP is disposed. For example, the plurality of signal lines may include a plurality of data lines DL which supplies a data voltage to each of the plurality of sub pixels SP and a plurality of scan lines SL which supplies a gate voltage to each of the plurality of sub pixels SP. The plurality of scan lines SL extends to one direction in the active area AA to be connected to the plurality of sub pixels SP and the plurality of data lines DL extends to a direction different from the one direction in the active area AA to be connected to the plurality of sub pixels SP. In addition, in the active area AA, a low potential power line, a high potential power line, and the like may be further disposed, but are not limited thereto.

The non-active area NA is an area where images are not displayed so that the non-active area NA may be defined as an area extending from the active area AA. In the non-active area NA, a link line which transmits a signal to the sub pixel SP of the active area AA, a pad electrode, or a driving IC, such as a gate driver IC or a data driver IC, may be disposed. The non-active area NA may be located on a rear surface of the display panel PN, that is, a surface on which the sub pixels SP are not disposed or may be omitted, and is not limited as illustrated in the drawing.

In the meantime, a driver, such as a gate driver GD, a data driver DD, and a timing controller TC, may be connected to the display panel PN in various ways. For example, the gate driver GD may be mounted in the non-active area NA in a gate in panel (GIP) manner or mounted between the plurality of sub pixels SP in the active area AA in a gate in active area (GIA) manner. For example, the data driver DD and the timing controller TC are formed in separate flexible film and printed circuit board and may be electrically connected to the display panel PN by bonding the flexible film and the printed circuit board to a pad electrode formed in the non-active area NA of the display panel PN. If the gate driver GD is mounted in the GIP manner and the data driver DD and the timing controller TC transmit a signal to the display panel PN through a pad electrode of the non-active area NA, an area of the non-active area NA to dispose the gate driver GD and the pad electrode needs to be ensured. By doing this, a bezel may be increased.

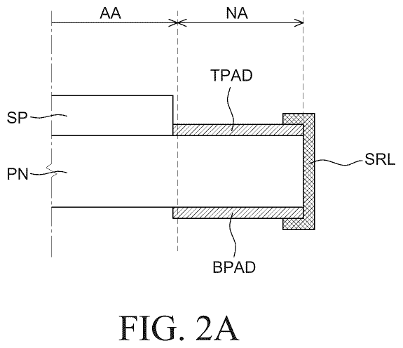

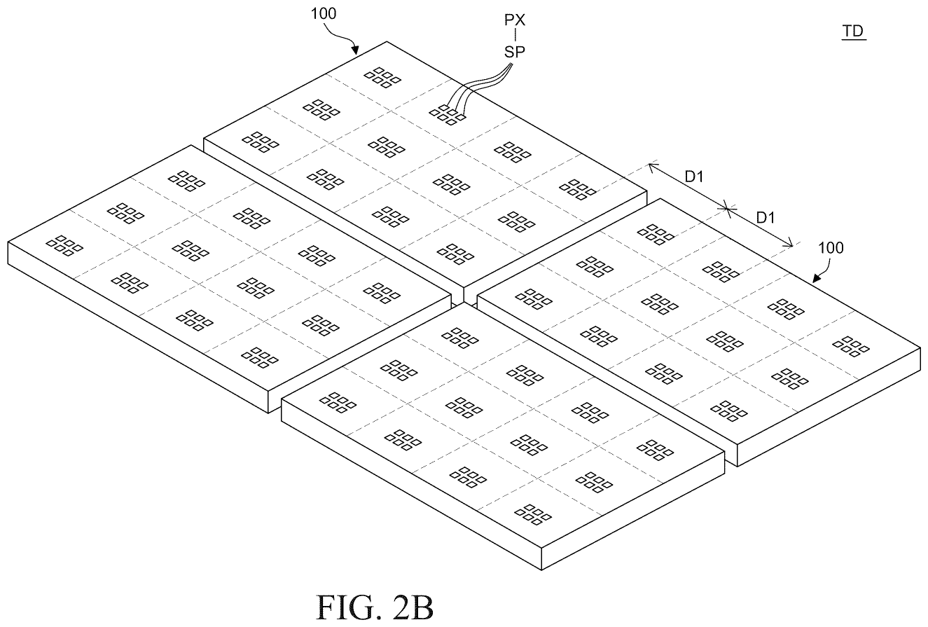

In contrast, when the gate driver GD is mounted in the active area AA in the GIA manner and side lines SRL which connects the signal lines on the front surface of the display panel PN to the pad electrodes on a rear surface of the display panel PN is formed to bond the flexible film and the printed circuit board onto a rear surface of the display panel PN, the non-active area NA may be minimized on the front surface of the display panel PN. That is, when the gate driver GD, the data driver DD, and the timing controller TC are connected to the display panel PN as described above, a zero bezel in which there is no bezel may be substantially implemented, which will be described in more detail with reference to FIGS. 2A and 2B.

FIG. 2A is a partial cross-sectional view of a display device according to an exemplary embodiment of the present disclosure. FIG. 2B is a perspective view of a tiling display device according to an exemplary embodiment of the present disclosure.

In the non-active area NA of the display panel PN, a plurality of pad electrodes for transmitting various signals to the plurality of sub pixels SP is disposed. For example, in a non-active area NA on the front surface of the display panel PN, a top pad TPAD which transmits a signal to the plurality of sub pixels SP is disposed. In a non-active area NA on the rear surface of the display panel PN, a bottom pad BPAD which is electrically connected to a driving component, such as a flexible film and the printed circuit board, is disposed.

In this case, even though it is not illustrated in the drawing, various signal lines connected to the plurality of sub pixels SP, for example, a scan line SL or a data line DL extend from the active area AA to the non-active area NA to be electrically connected to the top pad TPAD.

The side lines SRL is disposed along a side surface of the display panel PN. The side lines SRL may electrically connect the top pad TPAD of the front surface of the display panel PN and the bottom pad BPAD on the rear surface of the display panel PN. Therefore, a signal from a driving component on the rear surface of the display panel PN may be transmitted to the plurality of sub pixels SP through the bottom pad BPAD, the side lines SRL, and the top pad TPAD. Accordingly, a signal transmitting path from the front surface of the display panel PN to the side surface and the rear surface is formed to minimize an area of the non-active area NA of the display panel PN.

Referring to FIG. 2B, a tiling display device TD having a large screen size may be implemented by connecting a plurality of display devices 100. At this time, as illustrated in FIG. 2A, when the tiling display device TD is implemented using a display device 100 with a minimized bezel, a seam area in which an image between the display devices 100 is not displayed is minimized so that a display quality may be improved.

For example, the plurality of sub pixels SP may form one pixel PX and a distance D1 between an outermost pixel PX of one display device 100 and an outermost pixel PX of another display device 100 adjacent to one display device may be implemented to be equal to a distance D1 between pixels PX in one display device 100. Accordingly, the distance between pixels PX between the display devices 100 is constantly configured to minimize the seam area.

However, FIGS. 2A and 2B are illustrative so that the display device 100 according to the exemplary embodiment of the present disclosure may be a general display device with a bezel, but is not limited thereto.

In the meantime, the display panel PN may include a first substrate and a second substrate.

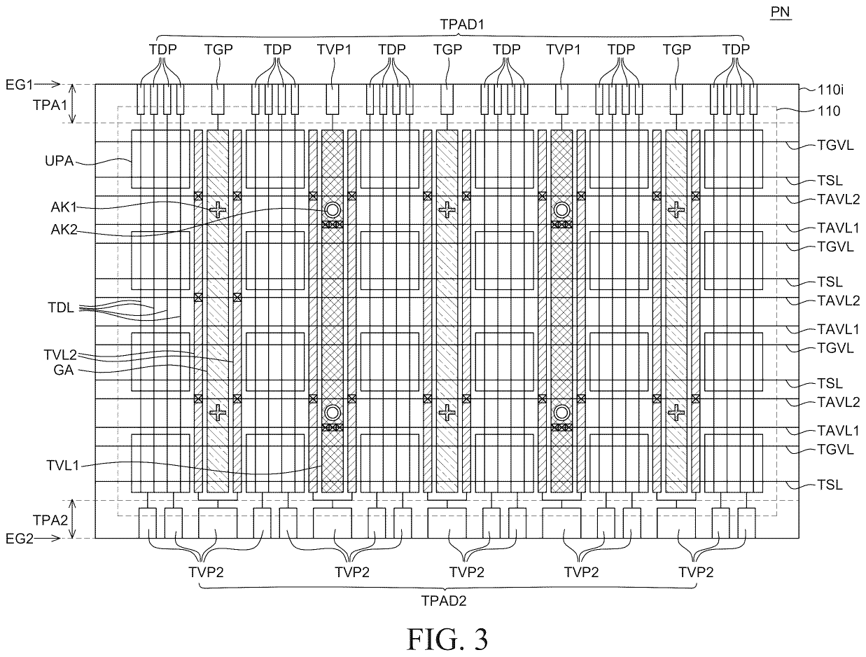

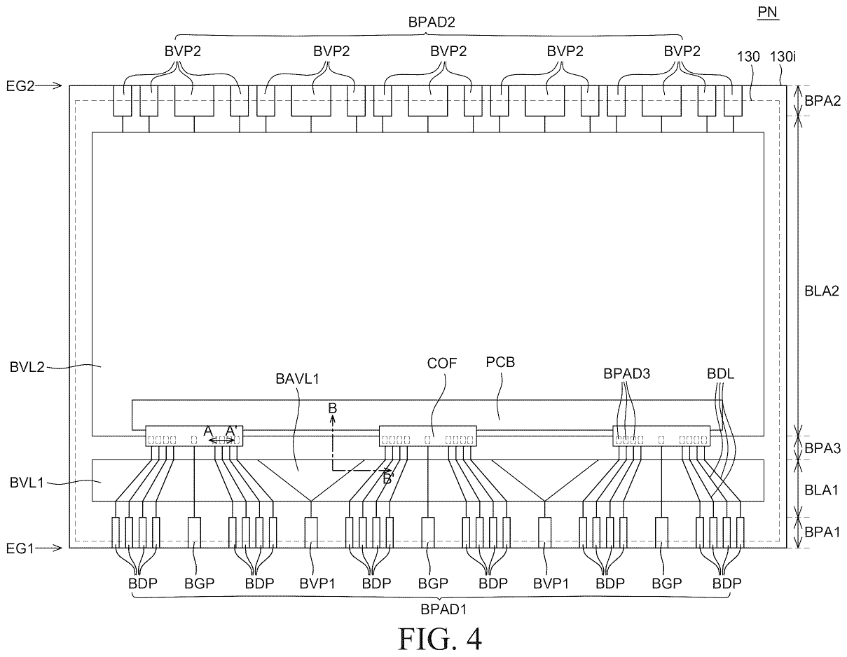

Hereinafter, the first substrate and the second substrate will be described in detail with reference to FIGS. 3 and 4.

FIG. 3 is an enlarged plan view of a first substrate of a display device according to an exemplary embodiment of the present disclosure.

First, the display panel PN includes a first substrate 110. The first substrate 110 is a substrate which supports components disposed above the display device 100 and may be an insulating substrate. A plurality of pixels PX is formed on the first substrate 110 to display images. For example, the first substrate 110 may be formed of glass, resin, or the like. Further, the first substrate 110 may include polymer or plastic. In some exemplary embodiments, the first substrate 110 may be formed of a plastic material having flexibility.

Referring to FIG. 3, in the first substrate 110, a plurality of pixel areas UPA, a plurality of gate driving areas GA, and a plurality of top pad areas are disposed. Among them, the plurality of pixel areas UPA and the plurality of gate driving areas GA may be included in the active area AA of the display panel PN.

First, the plurality of pixel areas UPA is areas in which the plurality of pixels PX is disposed. The plurality of pixel areas UPA may be disposed while forming a plurality of rows and a plurality of columns. Each of the plurality of pixels PX disposed in the plurality of pixel areas UPA includes a plurality of sub pixels SP. Each of the plurality of sub pixels SP includes a light emitting diode LED and a pixel circuit to independently emit light.

The display panel PN includes each of a plurality of pixels PX which is formed by a plurality of sub pixels SP. Each of the plurality of sub pixels SP includes a light emitting diode LED and a pixel circuit to independently emit light. One pixel may include one or more first sub pixels, one or more second sub pixels, and one or more third sub pixels. For example, one pixel may include two first sub pixels, two second sub pixels, and two third sub pixels. At this time, the first sub pixel may be a red sub pixel, the second sub pixel may be a green sub pixel, and the third sub pixel may be a blue sub pixel, but it is not limited thereto.

The plurality of gate driving areas GA is areas where gate drivers GD are disposed. The gate driver GD may be mounted in the active area AA in a gate in active area (GIA) manner. For example, the gate driving area GA may be formed along a row direction and/or column direction between the plurality of pixel areas UPA. The gate driver GD formed in the gate driving area GA may supply the scan signal to the plurality of scan lines SL.

The gate driver GD disposed in the gate driving area GA may include a circuit for outputting a scan signal. At this time, for example, the gate driver GD may include a plurality of transistors and/or capacitors. Here, active layers of the plurality of transistors may be formed of a semiconductor material, such as an oxide semiconductor, amorphous silicon, or polysilicon, but are not limited thereto. At this time, the active layers of the plurality of transistors may be formed of the same material or different materials from each other. Further, the active layers of the transistors of the gate driver may be formed of the same material as active layers of various transistors of the pixel circuit or formed of different materials from each other.

The plurality of top pad areas includes a first top pad area TPA1 located in a first edge EG1 of the display panel PN and a second top pad area TPA2 of the display panel PN located in a second edge EG2 of the display panel PN.

The first top pad area TPA1 and the second top pad area TPA2 are areas in which a plurality of top pads TPAD disposed on the first substrate 110 is disposed. The plurality of top pads TPAD may transmit various signals to various wiring lines extending in a column direction in the active area AA.

In the first top pad area TPA1, a plurality of first top pads TPAD1 may be disposed. The plurality of first top pads TPAD1 may include top pads TPAD to which different signals are applied. For example, the first top pad TPAD1 may include a top data pad TDP which transmits a data voltage to a top data line TDL, a top gate pad TGP which transmits a clock signal, a start signal, a gate low voltage, a gate high voltage, and the like for driving the gate driver GD to the gate driver GD, and a top high potential power pad TVP1 which transmits a high potential power voltage to the top high potential power line TVL1.

In the second top pad area TPA2, a plurality of second top pads TPAD2 may be disposed. At this time, the plurality of second top pads TPAD2 may be different from the plurality of first top pads TPAD1. For example, the plurality of second top pads TPAD2 may include a top low potential power pad TVP2 which transmits a low potential power voltage to the plurality of top low potential power lines TVL2.

At this time, the plurality of top pads TPAD may be formed to have different sizes, respectively. For example, the plurality of top data pads TDP which is connected to the plurality of top data lines TDL of the plurality of first top pads TPAD1 one to one may have a smaller width and the top high potential power pad TVP1 and the top gate pad TGP may have larger widths. Further, the top low potential power pad TVP2 which is the plurality of second top pads TPAD2 may also have a larger width than those of the plurality of top data pads TDP and the top low potential power pads TVP2 may have different widths, respectively. However, widths of the top data pad TDP, the top gate pad TGP, the top high potential power pad TVP1, and the top low potential power pads TVP2 illustrated in FIG. 3 are illustrative so that the top pad TPAD may be configured in various sizes, but is not limited thereto.

In the meantime, in order to reduce the bezel of the display panel PN, an edge of the display panel PN may be cut to be removed. The plurality of pixels PX, the plurality of wiring lines, and the plurality of top pads TPAD are formed on an initial first substrate 110i and an edge portion of the initial first substrate 110i is ground to reduce the bezel area. During the grinding process, a portion of the initial first substrate 110i is removed to form a first substrate 110 with a smaller size. At this time, parts of the plurality of top pads TPAD and wiring lines disposed at the edge of the first substrate 110 may be removed. Accordingly, only a portion of the plurality of top pads TPAD may remain on the first substrate 110.

A plurality of top data lines TDL extending from the plurality of top pads TPAD in the column direction is disposed in the plurality of pixel areas UPA on the first substrate 110 of the display panel PN. The plurality of top data lines TDL may extend from the plurality of top data pads TDP of the first top pad area TPA1 toward the plurality of pixel areas UPA. The plurality of top data lines TDL extends in a column direction and may be disposed to overlap the plurality of pixel areas UPA. Therefore, the plurality of top data lines TDL may transmit the data voltage to the pixel circuit of each of the plurality of sub pixels SP.

The plurality of top high potential power lines TVL1 extending in the column direction is disposed in the plurality of pixel areas UPA on the first substrate 110 of the display panel PN. Some of the plurality of top high potential power lines TVL1 extends from the top high potential power pad TVP1 of the first top pad area TPA1 to the plurality of pixel areas UPA to transmit the high potential power voltage to the light emitting diode LED of each of the plurality of sub pixels SP. The others of the plurality of top high potential power lines TVL1 may be electrically connected to the other top high potential power line TVL1 by means of a top auxiliary high potential power line TAVL1 to be described below. In FIG. 3, for the convenience of description, even though it is illustrated that one top high potential power line TVL1 and one top high potential power pad TVP1 are disposed, a plurality of top high potential power lines TVL1 and top high potential power pads TVP1 may be disposed.

The plurality of top low potential power lines TVL2 extending in the column direction is disposed in the plurality of pixel areas UPA on the first substrate 110 of the display panel PN. At least some of the plurality of top low potential power lines TVL2 extends from the top low potential power pad TVP2 of the second top pad area TPA2 to the plurality of pixel areas UPA to transmit the low potential power voltage to the pixel circuit of each of the plurality of sub pixels SP. The others of the plurality of top low potential power lines TVL2 may be electrically connected to the other top low potential power line TVL2 by means of a top auxiliary low potential power line TAVL2 to be described below.

The plurality of top scan lines TSL extending in the row direction is disposed in the plurality of pixel areas UPA on the first substrate 110 of the display panel PN. The plurality of top scan lines TSL extends in the row direction and may be disposed across the plurality of pixel areas UPA and the plurality of gate driving areas GA. The plurality of top scan lines TSL may transmit the scan signal from the gate driver GD to the pixel circuits of the plurality of sub pixels SP.

The plurality of top auxiliary high potential power lines TAVL1 extending in the row direction is disposed in the plurality of pixel areas UPA on the first substrate 110 of the display panel PN. The plurality of top auxiliary high potential power lines TAVL1 may be disposed in an area between the plurality of pixel areas UPA. The plurality of top auxiliary high potential power lines TAVL1 extending in the row direction is electrically connected to the plurality of top high potential power lines TVL1 extending in the column direction through a contact hole to form a mesh structure. Therefore, the plurality of top auxiliary high potential power lines TAVL1 and the plurality of top high potential power lines TVL1 are configured to form a mesh structure to minimize voltage drop and voltage deviation.

The plurality of top auxiliary low potential power lines TAVL2 extending in the row direction is disposed in the plurality of pixel areas UPA on the first substrate 110 of the display panel PN. The plurality of top auxiliary low potential power lines TAVL2 may be disposed in an area between the plurality of pixel areas UPA. The plurality of top auxiliary low potential power lines TAVL2 extending in the row direction is electrically connected to the plurality of top low potential power lines TVL2 extending in the column direction through a contact hole to form a mesh structure. Therefore, the plurality of top auxiliary low potential power lines TAVL2 and the plurality of top low potential power lines TVL2 are configured to form a mesh structure to reduce a resistance of the wiring line and minimize voltage deviation.

Referring to FIG. 3, the plurality of top gate driving lines TGVL extending in the row direction and the column direction is disposed in the plurality of pixel areas UPA on the first substrate 110 of the display panel PN. Some of the plurality of top gate driving lines TGVL extends from the top gate pad TGP of the first top pad area TPA1 to the gate driving area GA to transmit a signal to the gate driver GD. The others of the plurality of top gate driving lines TGVL extend in the row direction and may transmit the signal to the gate drivers GD of the plurality of gate driving areas GA. Therefore, various signals are transmitted from the top gate driving line TGVL to the gate driver GD to drive the gate driver GD.

The plurality of top gate driving lines TGVL may include wiring lines which transmit a clock signal, a start signal, a gate high voltage, and a gate low voltage to the gate driver GD. Therefore, various signals are transmitted from the top gate driving line TGVL to the gate driver GD to drive the gate driver GD.

For example, the plurality of top gate driving lines TGVL may include a gate power line which transmits a power voltage to the gate driver GD of the gate driving area GA. The plurality of gate power lines may include a first gate power line which transmits a gate high voltage to the gate driver GD and a second gate power line which transmits a gate low voltage to the gate driver GD.

A plurality of alignment keys AK1 and AK2 is disposed in an area between the plurality of pixel areas UPA in the display panel PN. The plurality of alignment keys AK1 and AK2 is used for alignment during the manufacturing process of the display panel PN. The plurality of alignment keys AK1 and AK2 includes a first alignment key AK1 and a second alignment key AK2.

The first alignment key AK1 may be disposed in the gate driving area GA of areas between the plurality of pixel areas UPA. The first alignment key AK1 may be used to inspect an alignment position of the plurality of light emitting diodes LED. For example, the first alignment key AK1 may have a cross shape, but is not limited thereto.

The second alignment key AK2 may be disposed to overlap the top high potential power line TVL1 of areas between the plurality of pixel areas UPA. In the top high potential power line TVL1, a hole overlapping the second alignment key AK2 is formed to divide the second alignment key AK2 and the top high potential power line TVL1. The second alignment key AK2 may be used to align the display panel PN and a donor. The display panel PN and the donor are aligned using the second alignment key AK2 and the plurality of light emitting diodes LED of the donor may be transferred onto the display panel PN. For example, the second alignment key AK2 may have a circular ring shape, but is not limited thereto.

FIG. 4 is an enlarged plan view of a second substrate of a display device according to an exemplary embodiment of the present disclosure.

First, the display panel PN includes a second substrate 130. The second substrate 130 is a substrate which supports components disposed below the display device 100 and may be an insulating substrate. For example, a plurality of flexible films COF and printed circuit boards PCB which transmit signals to the plurality of sub pixels SP may be disposed below the second substrate 130.

The second substrate 130 may be formed of glass, resin, or the like. Further, the second substrate 130 may include polymer or plastic. The second substrate 130 may be formed of the same material as the first substrate 110. In some exemplary embodiments, the second substrate 130 may be formed of a plastic material having flexibility.

Referring to FIG. 4, the second substrate 130 may include a plurality of bottom pad areas, a COF pad area BPA3, and a plurality of line areas.

The plurality of bottom pad areas is areas in which a plurality of bottom pads BPAD disposed below the second substrate 130 is disposed. For example, the plurality of bottom pad areas may include a first bottom pad area BPA1 located in a first edge EG1 of the display panel PN and a second bottom pad area BPA2 located in a second edge EG2. The plurality of bottom pads BPAD may transmit various signals to various wiring lines disposed in the plurality of bottom line areas.

Referring to FIG. 4, the plurality of first bottom pads BPAD1 may be disposed in the first bottom pad area BPA1. The plurality of first bottom pads BPAD1 may include a plurality of bottom pads BPAD to which different signals are applied. For example, the plurality of first bottom pads BPAD1 may include a bottom data pad BDP, a bottom gate pad BGP, and a bottom high potential power pad BVP1.

In the meantime, each of the plurality of bottom pads BPAD may be formed to have different sizes. For example, the plurality of first bottom pads BPAD1 may have different sizes, respectively. Specifically, the plurality of bottom data pads BDP which is connected to the plurality of bottom data lines BDL one to one may have a narrower width and the bottom high potential power pad BVP1 and the bottom gate pad BGP may have a larger width. However, the widths of the bottom data pad BDP, the bottom gate pad BGP, and the bottom high potential power pad BVP1 illustrated in FIG. 4 are illustrative and the sizes of the bottom pads BPAD may vary, but are not limited thereto.

In the second bottom pad area BPA2, a plurality of second bottom pads BPAD2 may be disposed. At this time, the plurality of second bottom pads BPAD2 may be bottom pads BPAD which are different from the plurality of first bottom pads BPAD1. For example, the plurality of second bottom pads BPAD2 may include a bottom low potential power pad BVP2 which transmits a low potential power voltage to the bottom low potential power line BVL2.

In the meantime, the plurality of second bottom pads BPAD2 may have different sizes, respectively. For example, each of the plurality of second bottom pads BPAD2 may have a smaller width than those of the plurality of bottom data pads BDP of the plurality of first bottom pads BPAD1, but is not limited thereto. Further, the width of the bottom low potential power pad BVP2 illustrated in FIG. 4 is illustrative and the sizes of the bottom pads BPAD may vary, but are not limited thereto.

In the meantime, in order to reduce the bezel of the display panel PN, an edge of the display panel PN may be cut to be removed. The plurality of pixels PX, the plurality of wiring lines, and the plurality of bottom pads BPAD are formed on an initial second substrate 130i and an edge portion of the initial second substrate 130i is ground together with the initial first substrate 110i to reduce the bezel area. During the grinding process, a portion of the initial second substrate 130i is removed to form a second substrate 130 with a smaller size. At this time, parts of the plurality of bottom pads BPAD and wiring lines disposed in the edge of the second substrate 130 may be removed. Accordingly, only a portion of the plurality of bottom pads BPAD may remain on a second substrate 130.

A COF pad area BPA3 is disposed between the first bottom pad area BPA1 and the second bottom pad area BPA2. For example, the COF pad area BPA3 may be disposed to be adjacent to the first bottom pad area BPA1 between the first bottom pad area BPA1 and the second bottom pad area BPA2, but is not limited thereto.

A plurality of COF pads BPAD3 is disposed in the COF pad area BPA3.

The plurality of COF pads BPAD3 is connected to a plurality of bottom lines disposed in a plurality of bottom line areas and may electrically connect the plurality of bottom lines, and the plurality of flexible films COF and printed circuit boards PCB.

For example, the plurality of bottom data link lines BDL is connected to the plurality of COF pads BPAD3 and the plurality of COF pads BPAD3 may be electrically connected to the plurality of flexible films COF. Accordingly, the plurality of COF pads BPAD3 may electrically connect the plurality of flexible films COF and the plurality of bottom data link lines BDL.

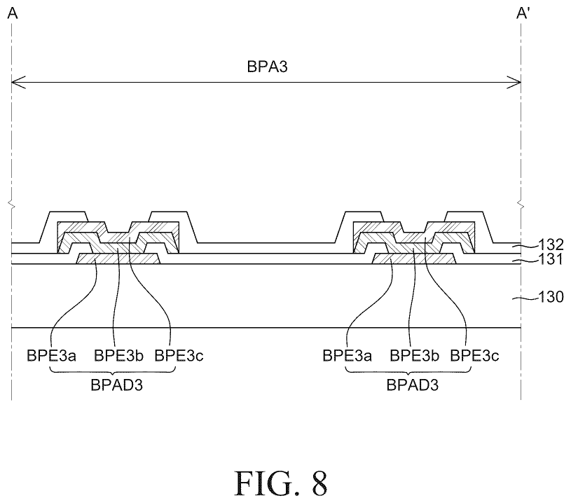

The plurality of COF pads BPAD3 will be described in detail with reference to FIG. 8.

In the meantime, the plurality of flexible films COF and printed circuit boards PCB may be disposed in the COF pad area BPA3.

The plurality of flexible films COF may be electrically connected to the plurality of COF pads BPAD3. The flexible film COF is a film in which various components are disposed on a base film having a ductility to supply a signal to the sub pixel SP and a driving component and may be electrically connected to the display panel PN.

A driving IC such as a gate driver IC or a data driver IC may be disposed on the plurality of flexible films COF. The driving IC is a component which processes data for displaying images and a driving signal for processing the data. The driving IC may be disposed in a chip on glass (COG), a chip on film (COF), or a tape carrier package (TCP) manner depending on a mounting method. However, for the convenience of description, it is described that the driving IC is mounted on the plurality of flexible films COF by a chip on film technique, but is not limited thereto.

The printed circuit board PCB is electrically connected to the plurality of flexible films COF. The printed circuit board PCB is a component which supplies signals to the driving IC. On the printed circuit board PCB, various components for supplying various signals to the driving IC may be disposed.

In the meantime, even though in FIG. 4, it is illustrated that three flexible films COF and one printed circuit board PCB are provided, the number of the plurality of flexible films COF and printed circuit boards PCB may vary depending on a design, but is not limited thereto.

The plurality of bottom line areas is areas in which a plurality of wiring lines connected to the plurality of bottom pads BPAD is disposed. The plurality of bottom line areas may include a first bottom line area BLA1 and a second bottom line area BLA2.

Referring to FIG. 4, the first bottom line area BLA1 and the second bottom line area BLA2 are disposed between the first bottom pad area BPA1 and the second bottom pad area BPA2. The first bottom line area BLA1 and the second bottom line area BLA2 may be disposed to be spaced apart from each other with the COF pad area BPA3 therebetween. For example, the first bottom line area BLA1 may be disposed between the first bottom pad area BPA1 and the COF pad area BPA3 and the second bottom line area BLA2 may be disposed between the second bottom pad area BPA2 and the COF pad area BPA3. Therefore, the first bottom pad area BPA1, the first bottom line area BLA1, the COF pad area BPA3, the second bottom line area BLA2, and the second bottom pad area BPA2 may be sequentially disposed from the first edge EG1 to the second edge EG2 of the display panel PN.

In the first bottom line area BLA1, the bottom data link line BDL, the bottom gate link line, the bottom high potential power line BVL1, and the plurality of bottom auxiliary high potential power lines BAVL1 may be disposed.

For example, a plurality of bottom data link lines BDL which extends from the bottom data pad BDP in the column direction is disposed in the first bottom line area BLA1 of the rear surface of the second substrate 130. The plurality of bottom data link lines BDL extends toward the COF pad area BPA3 to be connected to the plurality of flexible films COF and the printed circuit board PCB. Further, the plurality of bottom data link lines BDL may be disposed so as to overlap the bottom high potential power line BVL1.

A plurality of bottom gate link lines which extends from the bottom gate pad BGP in the column direction is disposed in the first bottom line area BLA1 of the rear surface of the second substrate 130. The plurality of bottom gate link lines extends toward the COF pad area BPA3 to be connected to the plurality of COF pads BPAD3.

A plurality of bottom high potential power link lines which extends from the plurality of bottom high potential power pads BVP1 in the column direction is disposed in the first bottom line area BLA1 of the rear surface of the second substrate 130.

Each of the plurality of bottom high potential power link lines extends in the column direction to be connected to the bottom high potential power line BVL1.

The bottom high potential power line BVL1 may have a long axis in the row direction.

For example, a width of the bottom high potential power line BVL1 may correspond to a width of the first bottom pad area BPA1. For example, a width of the bottom high potential power line BVL1 may correspond to a distance between outermost first bottom pads BPAD1, among the plurality of first bottom pads BPAD1. Therefore, the bottom high potential power line BVL1 may be in contact with each of the plurality of bottom high potential power link lines extending in the column direction.

A plurality of bottom auxiliary high potential power lines BAVL1 may be disposed in the first bottom line area BLA1. The plurality of bottom auxiliary high potential power lines BAVL1 is disposed to overlap the bottom high potential power line BVL1.

In the meantime, the more adjacent to the bottom low potential power line BVL2, the larger the width of each of the plurality of bottom auxiliary high potential power lines BAVL1. For example, a planar shape of the plurality of bottom auxiliary high potential power lines BAVL1 may be a triangle.

The plurality of bottom auxiliary high potential power lines BAVL1 are disposed to be spaced apart from each other between the flexible films COF and may alternately be disposed with the flexible film COF along the row direction.

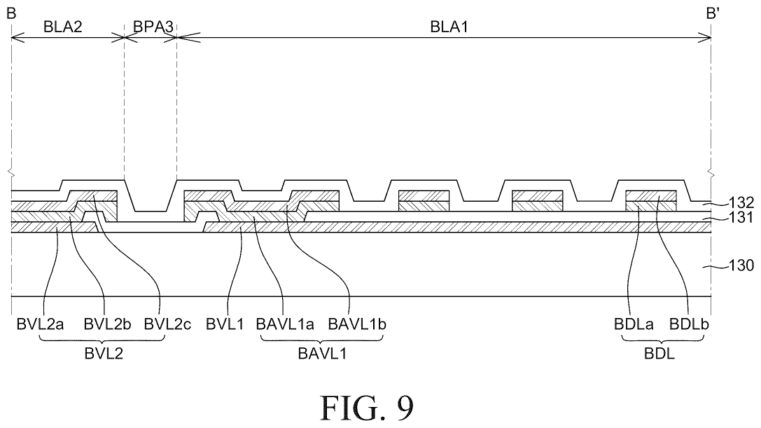

The plurality of bottom auxiliary high potential power lines BAVL1 and the plurality of bottom data link lines BDL will be described in detail below with reference to FIG. 9.

A plurality of bottom low potential power link lines which extends from the plurality of second bottom pads BPAD2 in the column direction is disposed in the second bottom line area BLA2 of the rear surface of the second substrate 130.

Each of the plurality of bottom low potential power link lines extends in the column direction to be connected to the bottom low potential power line BVL2.

The bottom low potential power line BVL2 may have a long axis in the row direction. For example, a width of the bottom low potential power line BVL2 may correspond to a width of the second bottom pad area BPA2. For example, a width of the bottom low potential power line BVL2 may correspond to a distance between outermost second bottom pads BPAD2, among the plurality of second bottom pads BPAD2. Therefore, the bottom low potential power line BVL2 may be in contact with each of the plurality of bottom low potential power link lines extending in the column direction.

In the meantime, each of the bottom data link line BDL, the bottom gate link line, the bottom high potential power link line disposed in the first bottom line area BLA1 of the second substrate 130 extends to the plurality of first bottom pads BPAD1 and may be connected to the plurality of first top pads TPAD1 disposed on the first substrate 110 through a first side lines to be described below.

The bottom low potential power link lines disposed in the second bottom line area BLA2 of the second substrate 130 extend to the plurality of second bottom pads BPAD2 and may be connected to the plurality of second top pads TPAD2 disposed on the first substrate 110 through second side lines to be described below.

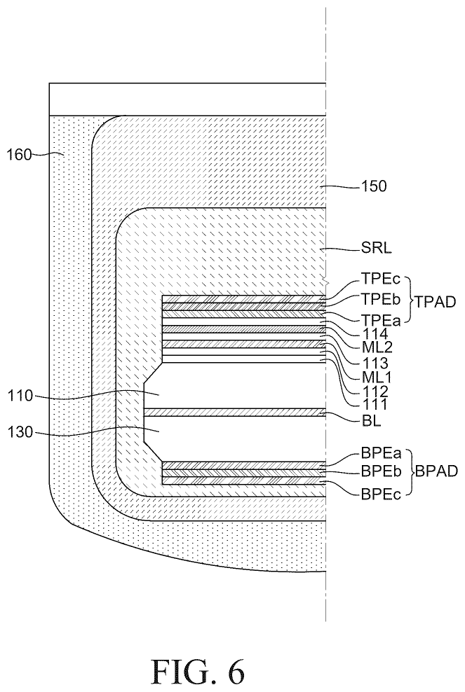

The side lines SRL will be described in detail below with reference to FIG. 6.

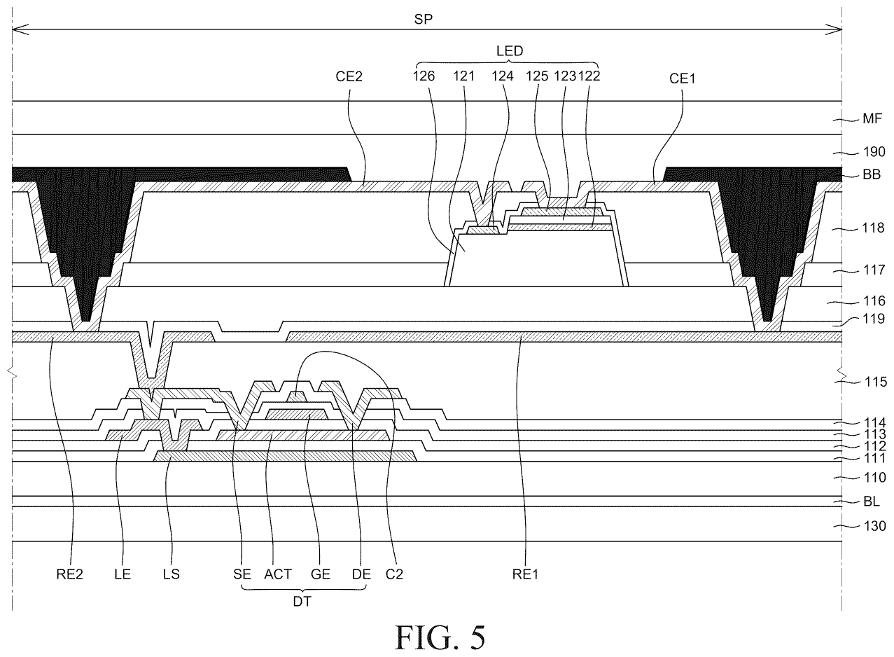

Hereinafter, the plurality of sub pixels SP of the pixel area UPA will be described in more detail with reference to FIG. 5.

FIG. 5 is a cross-sectional view of a sub pixel of a display device according to an exemplary embodiment of the present disclosure. In each of the plurality of sub pixels SP of the display panel PN of the display device 100 according to the exemplary embodiment of the present disclosure, a first substrate 110, a second substrate 130, a bonding layer BL, a buffer layer 111, a gate insulating layer 112, a first interlayer insulating layer 113, a second interlayer insulating layer 114, a first planarization layer 115, an adhesive layer 116, a second planarization layer 117, a third planarization layer 118, a passivation layer 119, a driving transistor DT, a light emitting diode LED, a plurality of reflective electrodes RE1 and RE2, a plurality of connection electrodes CE1 and CE2, a light shielding layer LS, and an auxiliary electrode LE are disposed.

First, the first substrate 110 is a component for supporting various components included in the display device 100 and may be formed of an insulating material. For example, the first substrate 110 may be formed of glass or resin. Further, the first substrate 110 may be configured to include polymer or plastics or may be formed of a material having flexibility.

The light shielding layer LS is disposed in each of the plurality of sub pixels SP on the first substrate 110. The light shielding layer LS blocks light incident onto an active layer ACT of the driving transistor DT to be described below, below the first substrate 110. Light which is incident onto the active layer ACT of the driving transistor DT is blocked by the light shielding layer LS to minimize a leakage current. For example, the light shielding layer LS may be formed of molybdenum (Mo), but is not limited thereto.

The buffer layer 111 is disposed on the first substrate 110 and the light shielding layer LS. The buffer layer 111 may reduce permeation of moisture or impurities through the first substrate 110. For example, the buffer layer 111 may be configured by a single layer or a double layer of silicon oxide (SiOx) or silicon nitride (SiNx), but is not limited thereto. However, the buffer layer 111 may be omitted depending on a type of the first substrate 110 or a type of transistor, but is not limited thereto.

The driving transistor DT is disposed on the buffer layer 111. The driving transistor DT includes an active layer ACT, a gate electrode GE, a source electrode SE, and a drain electrode DE.

The active layer ACT is disposed on the buffer layer 111. The active layer ACT may be formed of a semiconductor material, such as an oxide semiconductor, amorphous silicon, or polysilicon, but is not limited thereto.

The gate insulating layer 112 is disposed on the active layer ACT. The gate insulating layer 112 is an insulating layer which insulates the active layer ACT from the gate electrode GE and may be configured by a single layer or a double layer of silicon oxide (SiOx) or silicon nitride (SiNx), but is not limited thereto.

The gate electrode GE is disposed on the gate insulating layer 112. The gate electrode GE may be configured by a conductive material, such as copper (Cu), aluminum (Al), molybdenum (Mo), nickel (Ni), titanium (Ti), chrome (Cr), or an alloy thereof, but is not limited thereto.

The first interlayer insulating layer 113 is disposed on the gate electrode GE. In the first interlayer insulating layer 113, a contact hole through which the source electrode SE and the drain electrode DE are connected to the active layer ACT, respectively, is formed. The first interlayer insulating layer 113 is an insulating layer which protects components below the first interlayer insulating layer 113 and may be configured by a single layer or a double layer of silicon oxide (SiOx) or silicon nitride (SiNx), but is not limited thereto.

The capacitor electrode C2 is disposed on the first interlayer insulating layer 113. The capacitor electrode C2 may be disposed so as to overlap the gate electrode GE with the first interlayer insulating layer 113 therebetween.

The second interlayer insulating layer 114 is disposed on the capacitor electrode C2. In the second interlayer insulating layer 114, a contact hole through which the source electrode SE and the drain electrode DE are connected to the active layer ACT, respectively, is formed. The second interlayer insulating layer 114 is an insulating layer which protects components below the second interlayer insulating layer 114 and may be configured by a single layer or a double layer of silicon oxide SiOx or silicon nitride SiNx, but is not limited thereto.

The source electrode SE and the drain electrode DE which are electrically connected to the active layer ACT are disposed on the second interlayer insulating layer 114. The source electrode SE and the drain electrode DE may be configured by a conductive material, such as copper (Cu), aluminum (Al), molybdenum (Mo), nickel (Ni), titanium (Ti), chrome (Cr), or an alloy thereof, but are not limited thereto.

In the meantime, in the present disclosure, it is described that the first interlayer insulating layer 113 and the second interlayer insulating layer 114, that is, a plurality of insulating layers is disposed between the gate electrode GE, and the source electrode SE and the drain electrode DE. However, only one insulating layer may be disposed between the gate electrode GE, and the source electrode SE and the drain electrode DE.

As illustrated in the drawings, when a plurality of insulating layers, such as the first interlayer insulating layer 113 and the second interlayer insulating layer 114, is disposed between the gate electrode GE, and the source electrode SE and the drain electrode DE, an electrode may be further formed between the first interlayer insulating layer 113 and the second interlayer insulating layer 114. The additionally formed electrode may form a capacitor with the other configuration disposed below the first interlayer insulating layer 113 or above the second interlayer insulating layer 114.

The auxiliary electrode LE is disposed on the gate insulating layer 112. The auxiliary electrode LE is an electrode which electrically connects the light shielding layer LS below the buffer layer 111 to any one of the source electrode SE and the drain electrode DE on the second interlayer insulating layer 114. For example, the light shielding layer LS is electrically connected to any one of the source electrode SE or the drain electrode DE through the auxiliary electrode LE so as not to operate as a floating gate. Therefore, fluctuation of a threshold voltage of the driving transistor DT caused by the floated light shielding layer LS may be minimized.

Even though in the drawing, the light shielding layer LS is connected to the source electrode SE, the light shielding layer LS may also be connected to the drain electrode DE, but is not limited thereto.

The first planarization layer 115 is disposed on the driving transistor DT. The first planarization layer 115 may planarize an upper portion of the first substrate 110 on which the driving transistor DT is disposed. The first planarization layer 115 may be configured by a single layer or a double layer, and for example, may be formed of photoresist or an acrylic organic material, but is not limited thereto.

A plurality of reflective electrodes RE1 and RE2 which is spaced apart from each other is disposed on the first planarization layer 115. The plurality of reflective electrodes RE1 and RE2 electrically connects the light emitting diode LED to the power line and the driving transistor DT and may serve as a reflector which reflects light emitted from the light emitting diode LED to the upper portion of the light emitting diode LED. The plurality of reflective electrodes RE1 and RE2 is formed of a conductive material having the excellent reflecting property to reflect light emitted from the light emitting diode LED toward the upper portion of the light emitting diode LED.

For example, the plurality of reflective electrodes RE1 and RE2 may be configured by a conductive material such as copper (Cu), aluminum (Al), molybdenum (Mo), nickel (Ni), titanium (Ti), chrome (Cr), or an alloy thereof, but is not limited thereto.

The plurality of reflective electrodes RE1 and RE2 includes a first reflective electrode RE1 and a second reflective electrode RE2. The second reflective electrode RE2 may electrically connect the driving transistor DT and the light emitting diode LED. The second reflective electrode RE2 may be connected to the source electrode SE or the drain electrode DE of the driving transistor DT through a contact hole formed in the first planarization layer 115. The second reflective electrode RE2 may be electrically connected to the first electrode 124 of the light emitting diode LED through a second connection electrode CE2 to be described below.

The first reflective electrode RE1 may electrically connect the power line and the light emitting diode LED. The first reflective electrode RE1 may be connected to the power line and may be electrically connected to the second electrode 125 of the light emitting electrode LED through a first connection electrode CE1 to be described below.

The passivation layer 119 is disposed on the plurality of reflective electrodes RE1 and RE2. In the passivation layer 119, a contact hole through which the plurality of reflective electrodes RE1 and RE2 is coupled to the first connection electrode CE1 and the second connection electrode CE2, respectively, is disposed. The passivation layer 119 is an insulating layer which protects components below the passivation layer 119 and may be configured by a single layer or a double layer of silicon oxide (SiOx) or silicon nitride (SiNx), but is not limited thereto.

The adhesive layer 116 is disposed on the plurality of reflective electrodes RE. The adhesive layer 116 is coated on the front surface of the first substrate 110 to fix the light emitting diode LED disposed on the adhesive layer 116. For example, the adhesive layer 116 may be selected from any one of adhesive polymer, epoxy resin, UV resin, polyimide, acrylate, urethane, and polydimethylsiloxane (PDMS), but is not limited thereto.

The plurality of light emitting diodes LED is disposed in each of the plurality of sub pixels SP on the adhesive layer 116. The plurality of light emitting diodes LED is an element which emits light by a current and may include a light emitting diode LED which emits red light, green light, and blue light and may implement various colored light including white by a combination thereof. For example, the plurality of light emitting diodes LED may be a light emitting diode (LED) or a micro LED, but is not limited thereto.

The plurality of light emitting diodes LED may include a first light emitting diode, a second light emitting diode, and a third light emitting diode. In the first sub pixel, the first light emitting diode may be disposed, in the second sub pixel, the second light emitting diode may be disposed, and in the third sub pixel, the third light emitting diode may be disposed. For example, the first light emitting diode may be a red light emitting diode, the second light emitting diode may be a green light emitting diode, and the third light emitting diode may be a blue light emitting diode.

Each of the plurality of light emitting diodes LED includes a first semiconductor layer 121, an emission layer 122, a second semiconductor layer 123, a first electrode 124, a second electrode 125, and an encapsulation layer 126.

The first semiconductor layer 121 is disposed on the adhesive layer 116 and the second semiconductor layer 123 is disposed on the first semiconductor layer 121. The first semiconductor layer 121 and the second semiconductor layer 123 may be layers formed by doping n-type and p-type impurities into a specific material. For example, the first semiconductor layer 121 and the second semiconductor layer 123 may be layers doped with n-type and p-type impurities into a material such as gallium nitride (GaN), indium aluminum phosphide (InAlP), or gallium arsenide (GaAs). The p-type impurity may be magnesium), zinc (Zn), beryllium (Be), and the like, and the n-type impurity may be silicon (Si), germanium, tin (Sn), and the like, but are not limited thereto.

The emission layer 122 is disposed between the first semiconductor layer 121 and the second semiconductor layer 123. The emission layer 122 is supplied with holes and electrons from the first semiconductor layer 121 and the second semiconductor layer 123 to emit light. The emission layer 122 may be formed by a single layer or a multi-quantum well (MQW) structure, and for example, may be formed of indium gallium nitride (InGaN) or gallium nitride (GaN), but is not limited thereto.

The first electrode 124 is disposed on the first semiconductor layer 121. The first electrode 124 is an electrode which electrically connects the driving transistor DT and the first semiconductor layer 121. The first electrode 124 may be disposed on a top surface of the first semiconductor layer 121 which is exposed from the emission layer 122 and the second semiconductor layer 123. The first electrode 124 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 125 is disposed on the second semiconductor layer 123. The second electrode 125 may be disposed on the top surface of the second semiconductor layer 123. The second electrode 125 is an electrode which electrically connects the power line and the second semiconductor layer 123. The second electrode 125 may be configured by a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 126 which encloses the first semiconductor layer 121, the emission layer 122, the second semiconductor layer 123, the first electrode 124, and the second electrode 125 is disposed. The encapsulation layer 126 is formed of an insulating material to protect the first semiconductor layer 121, the emission layer 122, and the second semiconductor layer 123. In the encapsulation layer 126, a contact hole which exposes the first electrode 124 and the second electrode 125 is formed to electrically connect a first connection electrode CE1 and a second connection electrode CE2 to the first electrode 124 and the second electrode 125.

The second planarization layer 117 and the third planarization layer 118 are disposed on the adhesive layer 116. The second planarization layer 117 overlaps a portion of side surfaces of the plurality of light emitting diodes LED to fix and protect the plurality of light emitting diodes LED. Specifically, even though in FIG. 5, it is illustrated that the encapsulation layer 126 encloses all the side surfaces of the first semiconductor layer 121, a portion of the side surface of the first semiconductor layer 121 may be exposed from the encapsulation layer 126. The light emitting diode LED manufactured on the wafer is separated from the wafer to be transferred onto the display panel PN. However, during the process of separating the light emitting diode LED from the wafer, a portion of the encapsulation layer 126 may be torn. For example, a portion of the encapsulation layer 126 which is adjacent to a lower edge of the first semiconductor layer 121 of the light emitting diode LED is torn during the process of separating the light emitting diode LED from the wafer. Accordingly, a portion of a lower side surface of the first semiconductor layer 121 may be exposed to the outside. However, even though the lower portion of the light emitting diode LED is exposed from the encapsulation layer 126, the first connection electrode CE1 and the second connection electrode CE2 are formed after forming the second planarization layer 117 which covers the side surface of the first semiconductor layer 121. Accordingly, a short defect may be minimized.

Further, the third planarization layer 118 is formed to cover upper portions of the second planarization layer 117 and the light emitting diode LED and a contact hole which exposes the first electrode 124 and the second electrode 125 of the light emitting diode LED may be formed. The first electrode 124 and the second electrode 125 of the light emitting diode LED are exposed from the third planarization layer 118 and the third planarization layer 118 is partially disposed in an area between the first electrode 124 and the second electrode 125 to minimize a short defect.

The second planarization layer 117 and the third planarization layer 118 may be configured by a single layer or a double layer, and for example, may be formed of photoresist or an acrylic organic material, but is not limited thereto. Even though in the present disclosure, it is described that the second planarization layer 117 and the third planarization layer 118 are disposed, the planarization layer may be formed by a single layer, but is not limited thereto.

A plurality of connection electrodes CE1 and CE2 is disposed on the third planarization layer 118. The plurality of connection electrodes CE1 and CE2 includes a plurality of first connection electrodes CE1 and a second connection electrode CE2.

The second connection electrode CE2 is an electrode which is disposed in each of the plurality of sub pixels SP to electrically connect the light emitting diode LED and the driving transistor DT. The second connection electrode CE2 may be connected to the second reflective electrode RE2 through the contact hole formed in the third planarization layer 118, the second planarization layer 117, and the adhesive layer 116. Accordingly, the second connection electrode CE2 may be electrically connected to any one of the source electrode SE and the drain electrode DE of the driving transistor DT through the second reflective electrode RE2. The second connection electrode CE2 may be connected to the first electrode 124 of each of the plurality of light emitting diodes LED through a contact hole formed in the third planarization layer 118. Accordingly, the second connection electrode CE2 may electrically connect the driving transistor DT to the first electrode 124 of the plurality of light emitting diodes LED.

The first connection electrode CE1 is an electrode for electrically connecting the light emitting diode LED and the power line. The first connection electrode CE1 may be connected to the first reflective electrode RE1 through the contact hole formed in the third planarization layer 118, the second planarization layer 117, and the adhesive layer 116. Further, the first connection electrode CE1 may be electrically connected to the power line through the first reflective electrode RE1. The first connection electrode CE1 may be connected to the second electrode 125 of each of the plurality of light emitting diodes LED through a contact hole formed in the third planarization layer 118. Accordingly, the first connection electrode CE1 may electrically connect the power line to the second electrode 125 of the plurality of light emitting diodes LED.

The bank BB is disposed on the first connection electrode CE1 and the second connection electrode CE2. The bank BB may be disposed to be spaced apart from the light emitting diode LED with a predetermined interval.

The bank BB may be formed of an opaque material to reduce color mixture between the plurality of sub pixels SP and for example, may be formed of black resin, but is not limited thereto.

The protection layer 190 is disposed on the first connection electrode CE1, the second connection electrode CE2, and the bank BB. The protection layer 190 is a layer for protecting a configuration below the protection layer 190 and for example, may cover at least a portion of the light emitting diode LED. The protection layer 190 may be configured by a single layer or a double layer of translucent epoxy, silicon oxide SiOx or silicon nitride SiNx, but is not limited thereto.

In the meantime, the second connection electrode CE2 which connects the driving transistor DT and the light emitting diode LED which are disposed in each of the plurality of sub pixels SP may be individually disposed in each of the plurality of sub pixels SP.

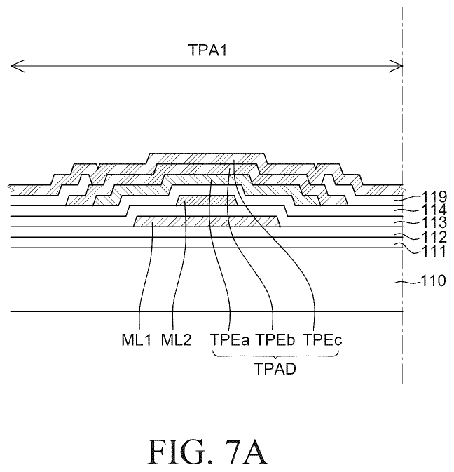

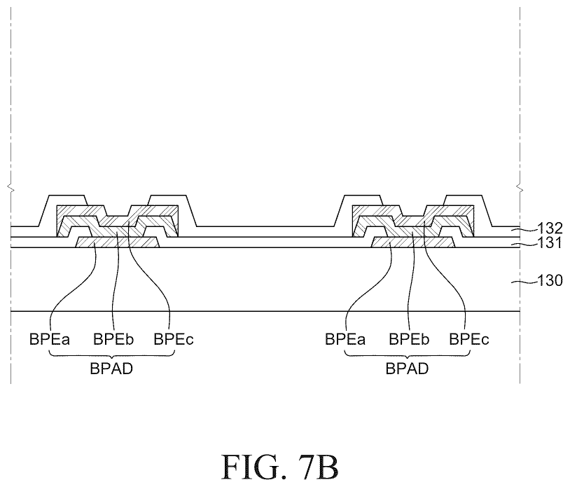

Hereinafter, a plurality of top pads TPAD and a plurality of bottom pads BPAD will be described in detail with reference to FIGS. 6 to 7B together.

FIG. 6 is a cross-sectional view of a pad area of a display device according to an exemplary embodiment of the present disclosure. FIG. 7A is a cross-sectional view of a top pad of a display device according to an exemplary embodiment of the present disclosure. FIG. 7B is a cross-sectional view of a bottom pad of a display device according to an exemplary embodiment of the present disclosure. In FIG. 7B, it is illustrated that positions of the second substrate 130 and components below the second substrate 130 are inverted so as to dispose the second substrate 130 at the bottom, for the convenience of illustration.

Referring to FIGS. 6 and 7A, each of a plurality of top pads TPAD may be formed by a plurality of conductive layers. For example, each of the plurality of top pads TPAD may include a first top pad electrode TPEa, a second top pad electrode TPEb, and a third top pad electrode TPEc. That is, each of the plurality of first top pads TPAD1 and the plurality of second top pads TPAD2 may include a first top pad electrode TPEa, a second top pad electrode TPEb, and a third top pad electrode TPEc.

First, the first top pad electrode TPEa is disposed on the second interlayer insulating layer 114. The first top pad electrode TPEa may be formed of the same conductive material as the source electrode SE and the drain electrode DE and for example, may be configured by copper (Cu), aluminum (Al), molybdenum (Mo), nickel (Ni), titanium (Ti), chrome (Cr), or an alloy thereof, but is not limited thereto.

The second top pad electrode TPEb is disposed on the first top pad electrode TPEa. The second top pad electrode TPEb may be formed of the same conductive material as the plurality of reflective electrodes RE1 and RE2. The second top pad electrode TPEb may be configured by a conductive material such as copper (Cu), aluminum (Al), molybdenum (Mo), nickel (Ni), titanium (Ti), chrome (Cr), or an alloy thereof, but is not limited thereto.

The third top pad electrode TPEc is disposed on the second top pad electrode TPEb. The third top pad electrode TPEc may be formed of the same conductive material as the first connection electrode CE1 and the second connection electrode CE2, and for example, a transparent conductive material, such as indium tin oxide (ITO) or indium zinc oxide (IZO), but is not limited thereto.0

At this time, even though it is not illustrated in the drawings, a portion of the plurality of top pad electrodes of the top pad TPAD is electrically connected to a plurality of wiring lines on the first substrate 110 to supply various signals to a plurality of wiring lines and a plurality of sub pixels SP. For example, the first top pad electrodes TPEa and/or the second top pad electrodes TPEb of the top pad TPAD is connected to the top data line TDL, the top high potential power line TVL1, the top low potential power line TVL2, and the like disposed in the active area AA to transmit signals thereto, respectively.

A first metal layer ML1, a second metal layer ML2, and a plurality of insulating layers may be disposed below the top pad TPAD. The first metal layer ML1, the second metal layer ML2, and the plurality of insulating layers are disposed below the top pad TPAD to adjust a step of the top pad TPAD. For example, the buffer layer 111, the gate insulating layer 112, the first metal layer ML1, the first interlayer insulating layer 113, and the second metal layer ML2 may be sequentially disposed between the top pad TPAD and the first substrate 110. The first metal layer ML1 may be formed of the same conductive material as the gate electrode GE and the second metal layer ML2 may be formed of the same conductive material as a capacitor electrode C2. However, the plurality of insulating layers, the first metal layer ML1, and the second metal layer ML2 below the top pad TPAD may be omitted depending on a design and are not limited thereto.

Referring to FIG. 5 together, a second substrate 130 is disposed below the first substrate 110. The second substrate 130 is a substrate which supports components disposed below the display device 100 and may be an insulating substrate. For example, the second substrate 130 may be formed of glass or resin. Further, the second substrate 130 may include polymer or plastic. The second substrate 130 may be formed of the same material as the first substrate 110. In some exemplary embodiments, the second substrate 130 may be formed of a plastic material having flexibility.

Referring to FIG. 5 together, a bonding layer BL is disposed between the first substrate 110 and the second substrate 130. The bonding layer BL may be formed of a material which is cured by various curing methods to bond the first substrate 110 and the second substrate 130. The bonding layer BL may be disposed only in a partial area between the first substrate 110 and the second substrate 130 or may be disposed in the entire area therebetween.

A plurality of bottom pads BPAD is disposed on the rear surface of the second substrate 130. The plurality of bottom pads BPAD is electrodes which transmit a signal from a driving component disposed on the rear surface of the second substrate 130 to a plurality of side lines SRL and a plurality of top pads TPAD and a plurality of wiring lines on the first substrate 110. The plurality of bottom pads BPAD is disposed in an end portion of the second substrate 130 in the non-active area NA to be electrically connected to the side lines SRL which covers the end portion of the second substrate 130.

At this time, the plurality of bottom pads BPAD may also be disposed so as to correspond to the plurality of bottom pad areas. Each of the plurality of top pads TPAD may be disposed so as to correspond to each of the plurality of bottom pads BPAD and then the top pads TPAD and the bottom pads BPAD which overlap each other through the side lines SRL may be electrically connected.

Each of the plurality of bottom pads BPAD includes a plurality of pad electrodes. For example, each of the plurality of bottom pads BPAD includes a first bottom pad electrode BPEa, a second bottom pad electrode BPEb, and a third bottom pad electrode BPEc. That is, each of the plurality of first bottom pads BPAD1 and the plurality of second bottom pads BPAD2 includes a first bottom pad electrode BPEa, a second bottom pad electrode BPEb, and a third bottom pad electrode BPEc.

In FIG. 7B, it is illustrated that the bottom pad BPAD is disposed on the second substrate 130 for the convenience of illustration and the first bottom pad electrode BPEa, the second bottom pad electrode BPEb, and the third bottom pad electrode BPEc are sequentially disposed above the second substrate 130.

However, the second substrate 130 illustrated in FIG. 7B is disposed upside down to be bonded to the first substrate 110. Therefore, in the bonded state of the second substrate 130 and the first substrate 110, as illustrated in FIG. 6, the plurality of bottom pads BPAD may be disposed below the second substrate 130. Further, the first bottom pad electrode BPEa, the second bottom pad electrode BPEb, and the third bottom pad electrode BPEc may be sequentially disposed below the second substrate 130.

Hereinafter, it is described based on a state in which the second substrate 130 is bonded to the first substrate 110 and it is described that the first bottom pad electrode BPEa, the second bottom pad electrode BPEb, and the third bottom pad electrode BPEc are sequentially disposed below the second substrate 130.

First, the first bottom pad electrode BPEa is disposed below the second substrate 130. The first bottom pad electrode BPEa may be configured by a conductive material such as copper (Cu), aluminum (Al), molybdenum (Mo), nickel (Ni), titanium (Ti), chrome (Cr), or an alloy thereof, but is not limited thereto.

The first insulating layer 131 is disposed below the first bottom pad electrode BPEa. Referring to FIG. 7B, the first insulating layer 131 may cover a side surface of the first bottom pad electrode BPEa. In the meantime, the first insulating layer 131 may include an opening which exposes a portion of one surface of the first bottom pad electrode BPEa.

The first insulating layer 131 may be an inorganic insulating layer. For example, the first insulating layer 131 may be configured by a single layer or a double layer of silicon oxide (SiOx) or silicon nitride (SiNx), but is not limited thereto.

The second bottom pad electrode BPEb is disposed below the first insulating layer 131. Referring to FIG. 7B, the second bottom pad electrode BPEb may be in contact with one surface of the first bottom pad electrode BPEa exposed by the opening of the first insulating layer 131.

The second bottom pad electrode BPEb may be configured by a conductive material such as copper (Cu), aluminum (Al), molybdenum (Mo), nickel (Ni), titanium (Ti), chrome (Cr), or an alloy thereof, but is not limited thereto.

The third bottom pad electrode BPEc is disposed below the second bottom pad electrode BPEb. Referring to FIG. 7B, the third bottom pad electrode BPEc may be in contact with one surface of the second bottom pad electrode BPEb.

In the meantime, referring to FIG. 7B, the third bottom pad electrode BPEc and the second bottom pad electrode BPEb may completely overlap. For example, an area in which the third bottom pad electrode BPEc and the second substrate 130 overlap may be equal to an area in which the second bottom pad electrode BPEb and the second substrate 130 overlap.

The third bottom pad electrode BPEc may be formed of a material which is hardly corroded even when in contact with air or moisture in order to suppress the corrosion of the second bottom pad electrode BPEb. For example, the third bottom pad electrode BPEc may be formed of a conductive material, for example, a transparent conductive material, such as indium tin oxide (ITO) or indium zinc oxide (IZO), but is not limited thereto.

The second insulating layer 132 is disposed below the third bottom pad electrode BPEc. The second insulating layer 132 may be an inorganic insulating layer. For example, the second insulating layer 132 may be configured by a single layer or a double layer of silicon oxide (SiOx) or silicon nitride (SiNx), but is not limited thereto.

In the meantime, the second insulating layer 132 may open a portion of the third bottom pad electrode BPEc and may also cover a portion of an edge of the third bottom pad electrode BPEc.

The third bottom pad electrode BPEc exposed by the second insulating layer 132 may be in contact with side lines SRL to be described below.

In the meantime, the first bottom pad electrode BPEa, the second bottom pad electrode BPEb, and the third bottom pad electrode BPEc of the plurality of bottom pads BPAD extend toward the plurality of flexible films COF disposed on the rear surface of the second substrate 130 to be electrically connected to the plurality of flexible films COF. The plurality of flexible films COF may supply various signals to the plurality of side lines SRL, the plurality of top pads TPAD, the plurality of wiring lines, and the plurality of sub pixels SP through the plurality of bottom pads BPAD. Therefore, the signal from the driving component may be transmitted to the signal line and the plurality of sub pixels SP on the front surface of the first substrate 110 through the plurality of bottom pads BPAD of the second substrate 130, the side lines SRL, and the plurality of top pads TPAD of the first substrate 110.

Referring to FIG. 6 again, the plurality of side lines SRL is disposed on the side surfaces of the first substrate 110 and the second substrate 130. The plurality of side lines SRL may electrically connect the plurality of top pads TPAD formed on the top surface of the first substrate 110 and the plurality of bottom pads BPAD formed on the rear surface of the second substrate 130. For example, the plurality of side lines SRL may be disposed so as to enclose the side surface of the display device 100 while being in contact with the third top pad electrode TPEc and the third bottom pad electrode BPEc. Each of the plurality of side lines SRL may cover the plurality of top pads TPAD at an end portion of the first substrate 110, a side surface of the first substrate 110, a side surface of the second substrate 130, and the plurality of bottom pads BPAD at an end portion of the second substrate 130. For example, the plurality of side lines SRL may be formed by a pad printing method using a conductive ink including silver (Ag), copper (Cu), molybdenum (Mo), and chrome (Cr).

The plurality of side lines SRL may include a plurality of first side lines and a plurality of second side lines. The plurality of first side lines is disposed so as to correspond to a first edge EG1 of the first substrate 110 and a first edge EG1 of the second substrate 130 and the plurality of second side lines is disposed so as to correspond to a second edge EG2 of the first substrate 110 and a second edge EG2 of the second substrate 130.

Therefore, among the plurality of side lines SRL, the plurality of first side lines may connect the plurality of first top pads TPAD1 and the plurality of first bottom pads BPAD1 and the plurality of second side lines may connect the plurality of second top pads TPAD2 and the plurality of second bottom pads BPAD2.

Referring to FIG. 6, a side insulating layer 150 which covers the plurality of side lines SRL is disposed. The side insulating layer 150 may be formed on the top surface of the first substrate 110, the side surface of the first substrate 110, the side surface of the second substrate 130, and the rear surface of the second substrate 130 to cover the side lines SRL. The side insulating layer 150 may protect the plurality of side lines SRL.

In the meantime, when the plurality of side lines SRL is formed of a metal material, there may be a problem in that external light is reflected from the plurality of side lines SRL or light emitted from the light emitting diode LED is reflected from the plurality of side lines SRL to be visibly recognized by the user. Therefore, the side insulating layer 150 is configured to include a black material to suppress reflection of the external light. For example, the side insulating layer 150 may be formed by a pad printing method using an insulating material including a black material, for example, a black ink.

A seal member 160 which covers the side insulating layer 150 is disposed. The seal member 160 is disposed so as to enclose the side surface of the display device 100 to protect the display device 100 from external impacts, moisture, and oxygen. For example, the seal member 160 may be formed of polyimide (PI), poly urethane, epoxy, or acryl based insulating material, but is not limited thereto.

An optical film MF is disposed on the seal member 160, the side insulating layer 150, and the protection layer 190. The optical film MF may be a functional film which implements a higher quality of images while protecting the display device 100. For example, the optical film MF may include an anti-scattering film, an anti-glare film, an anti-reflecting film, a low-reflecting film, an OLED transmittance controllable film, or a polarizer, but is not limited thereto.

In the meantime, even though an adhesive layer may be further disposed between the optical film MF and the seal member 160 and the side insulating layer 150 and the protection layer 190, in FIGS. 5 and 6, the adhesive layer is not illustrated for the sake of convenience. Alternatively, the optical film MF may also be defined to include an adhesive layer disposed therebelow.

An edge of the seal member 160 and an edge of the optical film MF may be disposed on the same line. The optical film MF having a larger size is attached above the first substrate 110 during the manufacturing process of the display device 100 and the seal member 160 which covers the side insulating layer 150 may be formed. Thereafter, the laser is irradiated on the seal member 160 and the optical film MF so as to correspond to an edge of the display device 100 to cut parts of the seal member 160 and the optical film MF. Accordingly, the size of the display device 100 is adjusted by an outer periphery cutting process of the seal member 160 and the optical film MF and the edge of the display device 100 may be formed to be flat.

Hereinafter, a COF pad area BPA3 of the display device according to the exemplary embodiment of the present disclosure will be described in more detail with reference to FIG. 8.

FIG. 8 is a cross-sectional view of a second substrate taken along line A-A′ of FIG. 4. FIG. 8 is a cross-sectional view for a COF pad area BPA3. In FIG. 8, for the convenience of illustration, the flexible film COF is not illustrated, but the COF pad BPAD3 is illustrated. In FIG. 8, for the convenience of illustration, it is illustrated that the positions of the second substrate 130 and the COF pad BPAD3 are inverted and the second substrate 130 is disposed at the bottom in the drawing.

Referring to FIG. 8, a plurality of COF pads BPAD3 is disposed in the COF pad area BPA3.

Each of the plurality of COF pads BPAD3 may be formed by a plurality of conductive layers. For example, each of the plurality of COF pads BPAD3 may include a first COF pad electrode BPE3a, a second COF pad electrode BPE3b, and a third COF pad electrode BPE3c.

In FIG. 8, it is illustrated that the COF pad BPAD3 is disposed on the second substrate 130 for the convenience of illustration and the first COF pad electrode BPE3a, the second COF pad electrode BPE3b, and the third COF pad electrode BPE3c are sequentially disposed above the second substrate 130.

However, the second substrate 130 illustrated in FIG. 8 is disposed upside down to be bonded to the first substrate 110. Therefore, in the bonded state of the second substrate 130 and the first substrate 110, the plurality of COF pads BPAD3 may be disposed below the second substrate 130. Further, the first COF pad electrode BPE3a, the second COF pad electrode BPE3b, and the third COF pad electrode BPE3c may be sequentially disposed below the second substrate 130.

Hereinafter, it is described based on a state in which the second substrate 130 is bonded to the first substrate 110 and it is described that the first COF pad electrode BPE3a, the second COF pad electrode BPE3b, and the third COF pad electrode BPE3c are sequentially disposed below the second substrate 130.

The first COF pad electrode BPE3a is disposed below the second substrate 130.

The first COF pad electrode BPE3a may be formed of the same material as the first bottom pad electrode BPEa. For example, the first COF pad electrode BPE3a may be configured by copper (Cu), aluminum (Al), molybdenum (Mo), nickel (Ni), titanium (Ti), chrome (Cr), or an alloy thereof, but is not limited thereto.

The second COF pad electrode BPE3b is disposed below the first COF pad electrode BPE3a. The second COF pad electrode BPE3b may be in contact with one surface of the first COF pad electrode BPE3a exposed by the first insulating layer 131.

The second COF pad electrode BPE3b may be formed of the same material as the second bottom pad electrode BPEb. For example, the second COF pad electrode BPE3b may be configured by a conductive material, such as copper (Cu), aluminum (Al), molybdenum (Mo), nickel (Ni), titanium (Ti), chrome (Cr), or an alloy thereof, but is not limited thereto.

The third COF pad electrode BPE3c is disposed below the second COF pad electrode BPE3b. The third COF pad electrode BPE3c may be in contact with one surface of the second COF pad electrode BPE3b.

The third COF pad electrode BPE3c and the second COF pad electrode BPE3b may completely overlap. For example, an area in which the third COF pad electrode BPE3c and the second substrate 130 overlap is equal to an area in which the second COF pad electrode BPE3b and the second substrate 130 overlap.

The third COF pad electrode BPE3c may be formed of the same material as the third bottom pad electrode BPEc. For example, the third COF pad electrode BPE3c may be formed of a material which is hardly corroded even when in contact with air or moisture in order to suppress the corrosion of the second COF pad electrode BPE3b. For example, the third COF pad electrode BPE3c may be formed of a conductive material, for example, a transparent conductive material, such as indium tin oxide (ITO) or indium zinc oxide (IZO), but is not limited thereto.

The plurality of COF pads BPAD3 may be electrically connected to the plurality of flexible films COF through the third COF pad electrode BPE3c, among the plurality of conductive layers which configures the plurality of COF pads BPAD3, respectively. That is, the plurality of COF pads BPAD3 may be electrically connected to an external module through the third COF pad electrode BPE3c.

For example, the plurality of COF pads BPAD3 may be electrically connected to the plurality of flexible films COF through the third COF pad electrode BPE3c which is exposed by the second insulating layer 132.

Even though it is not illustrated in FIG. 8, the plurality of COF pads BPAD3 may be electrically connected to the plurality of flexible films COF through the third COF pad electrode BPE3c, among the plurality of conductive layers which configures the plurality of COF pads BPAD3, respectively.

The plurality of COF pads BPAD3 may be connected to the plurality of flexible films COF through the adhesive layer. For example, the adhesive layer may be an anisotropic conductive film (ACF) or a conductive paste. Further, for example, the plurality of flexible films COF may be electrically connected to the plurality of COF pads BPAD3 of the second substrate 130 by heat and a pressure.

Hereinafter, a bottom power line will be described in detail with reference to FIG. 9.

FIG. 9 is a cross-sectional view of a second substrate taken along line B-B′ of FIG. 4. FIG. 9 is a cross-sectional view of a first bottom line area BLA1 and a second bottom line area BLA2. In FIG. 9, it is illustrated that positions of the second substrate 130 and components below the second substrate 130 are inverted so as to dispose the second substrate 130 at the bottom, for the convenience of description.

Referring to FIG. 9, a bottom high potential power line BVL1, a bottom auxiliary high potential power line BAVL1, and a plurality of bottom data link lines BDL are disposed in the first bottom line area BLA1.

In FIG. 9, for the convenience of illustration, a bottom high potential power line BVL1, a bottom auxiliary high potential power line BAVL1, and a plurality of bottom data link lines BDL are disposed on the second substrate 130.

However, the second substrate 130 illustrated in FIG. 9 is disposed upside down to be bonded to the first substrate 110. Therefore, in the bonded state of the second substrate 130 and the first substrate 110, the bottom high potential power line BVL1, the bottom auxiliary high potential power line BAVL1, and the plurality of bottom data link lines BDL may be disposed below the second substrate 130.

Therefore, it is described based on a state in which the second substrate 130 is bonded to the first substrate 110 and it is described that the bottom high potential power line BVL1, the bottom auxiliary high potential power line BAVL1, and the plurality of bottom data link lines BDL are disposed below the second substrate 130.

The bottom high potential power line BVL1 is disposed below the second substrate 130.

The bottom high potential power line BVL1 may be formed of the same material as the first bottom pad electrode BPEa and the first COF pad electrode BPE3a. For example, the bottom high potential power line BVL1 may be configured by a conductive material, such as copper (Cu), aluminum (Al), molybdenum (Mo), nickel (Ni), titanium (Ti), chrome (Cr), or an alloy thereof, but is not limited thereto.

The first insulating layer 131 is disposed below the bottom high potential power line BVL1. The first insulating layer 131 may include a plurality of openings disposed in a position overlapping the plurality of bottom auxiliary high potential power lines BAVL1. In the meantime, the first insulating layer 131 is disposed so as to overlap the plurality of bottom data link line BDL to insulate the bottom high potential power line BVL1 from the plurality of bottom data link lines BDL.

The plurality of bottom auxiliary high potential power lines BAVL1 and the plurality of bottom data link lines BDL are disposed below the first insulating layer 131.

First, the plurality of bottom auxiliary high potential power lines BAVL1 is disposed below the first insulating layer 131.

The plurality of bottom auxiliary high potential power lines BAVL1 may be in contact with the front surface of the bottom high potential power line BVL1 exposed by the first insulating layer 131. For example, the first insulating layer 131 and the plurality of bottom auxiliary high potential power lines BAVL1 are disposed below the bottom high potential power line BVL1 and the first insulating layer 131 may be disposed in an area other than between the flexible films COF. Therefore, the plurality of bottom auxiliary high potential power lines BAVL1 may be in contact with the bottom high potential power line BVL1 in an area between the flexible films COF in which the first insulating layer 131 is open.

Therefore, the plurality of bottom auxiliary high potential power lines BAVL1 is in contact with the bottom high potential power line BVL1 to minimize voltage drop and voltage deviation.

Each of the plurality of bottom auxiliary high potential power lines BAVL1 includes a first bottom auxiliary high potential power line BAVL1a and a second bottom auxiliary high potential power line BAVL1b.

The first insulating layer 131 is disposed below the second substrate 130, and a part of the first bottom auxiliary high potential power line BAVL1a is disposed below the first insulating layer 131, and the other part is disposed on the same layer as the first insulating layer 131.

The first bottom auxiliary high potential power line BAVL1a may be formed of the same material as the second bottom pad electrode BPEb and the second COF pad electrode BPE3b. For example, the first bottom auxiliary high potential power line BAVL1a may be configured by a conductive material, such as copper (Cu), aluminum (Al), molybdenum (Mo), nickel (Ni), titanium (Ti), chrome (Cr), or an alloy thereof, but is not limited thereto.

The second bottom auxiliary high potential power line BAVL1b is disposed below the first bottom auxiliary high potential power line BAVL1a.

The second bottom auxiliary high potential power line BAVL1b may be formed of the same material as the third bottom pad electrode BPEc and the third COF pad electrode BPE3c. For example, the second bottom auxiliary high potential power line BAVL1b may be formed of a material which is hardly corroded even when in contact with air or moisture in order to suppress the corrosion of the first bottom auxiliary high potential power line BAVL1a. For example, the second bottom auxiliary high potential power line BAVL1b may be formed of a conductive material, for example, a transparent conductive material, such as indium tin oxide (ITO) or indium zinc oxide (IZO), but is not limited thereto.

The second bottom auxiliary high potential power line BAVL1b may be in contact with the front surface of the first bottom auxiliary high potential power line BAVL1a. In the meantime, the second bottom auxiliary high potential power line BAVL1b may completely overlap the first bottom auxiliary high potential power line BAVL1a. For example, an area in which the second bottom auxiliary high potential power line BAVL1b and the second substrate 130 overlap may be equal to an area in which the first bottom auxiliary high potential power line BAVL1a and the second substrate 130 overlap.

The plurality of bottom auxiliary high potential power lines BAVL1 may be formed of the same material as the second bottom pad electrode BPEb and the second COF pad electrode BPE3b.

For example, the plurality of bottom auxiliary high potential power lines BAVL1 may be configured by a conductive material, such as copper (Cu), aluminum (Al), molybdenum (Mo), nickel (Ni), titanium (Ti), chrome (Cr), or an alloy thereof, but is not limited thereto.

A plurality of bottom data link lines BDL is disposed below the first insulating layer 131.

The plurality of bottom data link lines BDL may be disposed on the same layer as the plurality of bottom auxiliary high potential power lines BAVL1.

Further, the plurality of bottom data link lines BDL may be disposed so as to overlap the bottom high potential power line BVL1. For example, the plurality of bottom data link lines BDL may be disposed so as to overlap the bottom high potential power line BVL1 with the first insulating layer 131 therebetween.

Each of the plurality of bottom data link lines BDL includes a first bottom data link line BDLa and a second bottom data link line BDLb.

The first insulating layer 131 is disposed below the second substrate 130 and the first bottom data link line BDLa is disposed below the first insulating layer 131.

The first bottom data link line BDLa may be formed of the same material as the second bottom pad electrode BPEb and the second COF pad electrode BPE3b. For example, the first bottom data link line BDLa may be configured by a conductive material such as copper (Cu), aluminum (Al), molybdenum (Mo), nickel (Ni), titanium (Ti), chrome (Cr), or an alloy thereof, but is not limited thereto.

The second bottom data link line BDLb is disposed below the first bottom data link line BDLa.

The second bottom data link line BDLb may be formed of the same material as the third bottom pad electrode BPEc and the third COF pad electrode BPE3c. For example, the second bottom data link line BDLb may be formed of a material which is hardly corroded even when in contact with air or moisture in order to suppress the corrosion of the first bottom data link line BDLa. For example, the second bottom data link line BDLb may be formed of a conductive material, for example, a transparent conductive material, such as indium tin oxide (ITO) or indium zinc oxide (IZO), but is not limited thereto.

The second bottom data link line BDLb may be in contact with the front surface of the first bottom data link line BDLa. In the meantime, the second bottom data link line BDLb may completely overlap the first bottom data link line BDLa. For example, an area in which the second bottom data link line BDLb and the second substrate 130 overlap may be equal to an area in which the first bottom data link line BDLa and the second substrate 130 overlap.

The bottom low potential power line BVL2 is disposed in the second bottom line area BLA2.

For the convenience of illustration, in FIG. 9, it is illustrated that the bottom low potential power line BVL2 is disposed on the second substrate 130 and the second substrate 130 illustrated in FIG. 9 is located upside down to be bonded to the first substrate 110. Therefore, in a state in which the second substrate 130 and the first substrate 110 are bonded, the bottom low potential power line BVL2 may be disposed below the second substrate 130.

Hereinafter, it is described based on a state in which the second substrate 130 is bonded to the first substrate 110, and it is described that the bottom low potential power line BVL2 is disposed below the second substrate 130.

The bottom low potential power line BVL2 includes a first bottom low potential power line BVL2a, a second bottom low potential power line BVL2b, and a third bottom low potential power line BVL2c.

The first bottom low potential power line BVL2a is disposed below the second substrate 130.

The first bottom low potential power line BVL2a may be formed of the same material as the first bottom pad electrode BPEa and the first COF pad electrode BPE3a. For example, the first bottom low potential power line BVL2a may be configured by a conductive material, such as copper (Cu), aluminum (Al), molybdenum (Mo), nickel (Ni), titanium (Ti), chrome (Cr), or an alloy thereof, but is not limited thereto.

The first insulating layer 131 is disposed below the first bottom low potential power line BVL2a, and a part of the second bottom low potential power line BVL2b is disposed below the first insulating layer 131, and the other part is disposed on the same layer as the first insulating layer 131.

The second bottom low potential power line BVL2b may be in contact with the front surface of the first bottom low potential power line BVL2a exposed by the first insulating layer 131. For example, the first insulating layer 131 and the second bottom low potential power line BVL2b are disposed below the first bottom low potential power line BVL2a and the first insulating layer 131 may be disposed in an area excluding the second bottom line area BLA2. Therefore, the second bottom low potential power line BVL2b may be in contact with the first bottom low potential power line BVL2a in the second bottom line area BLA2.

The second bottom low potential power line BVL2b may be formed of the same material as the second bottom pad electrode BPEb and the second COF pad electrode BPE3b. For example, the second bottom low potential power line BVL2b may be configured by a conductive material, such as copper (Cu), aluminum (Al), molybdenum (Mo), nickel (Ni), titanium (Ti), chrome (Cr), or an alloy thereof, but is not limited thereto.

The third bottom low potential power line BVL2c may be disposed below the second bottom low potential power line BVL2b.

The third bottom low potential power line BVL2c may be in contact with the front surface of the second bottom low potential power line BVL2b.

The third bottom low potential power line BVL2c may be formed of the same material as the third bottom pad electrode BPEc and the third COF pad electrode BPE3c. For example, the third bottom low potential power line BVL2c may be formed of a conductive material, for example, a transparent conductive material, such as indium tin oxide (ITO) or indium zinc oxide (IZO), but is not limited thereto.

In the meantime, the third bottom low potential power line BVL2c may completely overlap the second bottom low potential power line BVL2b. For example, an area in which the third bottom low potential power line BVL2c and the second substrate 130 overlap may be equal to an area in which the second bottom low potential power line BVL2b and the second substrate 130 overlap.

When a plurality of metal layers disposed on the display panel is exposed to the outside, the plurality of metal layers reacts with air or moisture to be corroded. For example, the plurality of top pads disposed on the first substrate and the plurality of bottom pads disposed below the second substrate react with the air or moisture to be corroded. Therefore, in order to suppress the corrosion of the plurality of top pads and the plurality of bottom pads, a transparent conductive layer may be used as the plurality of pad electrodes which configures the plurality of top pads and the plurality of bottom pads. At this time, a plurality of power line or a plurality of data lines may be disposed on the same layer as transparent conductive layers of the plurality of top pads and the plurality of bottom pads. However, when the plurality of power lines or the plurality of data lines are formed with the transparent conductive layer, a separate mask process for patterning the transparent conductive layer is performed. For example, a process of forming an insulating layer, such as an organic insulating layer, above or below the transparent conductive layer may be added. Accordingly, there are problems in that the number of masks is increased and a manufacturing cost and a manufacturing time are increased.

In the meantime, a wiring line formed of the transparent conductive layer may be disposed so as to overlap the metal layer line having a different load. For example, the low potential power line formed of the transparent conductive layer on the rear surface of the second substrate may be disposed so as to overlap the data line and the high potential power line. At this time, a potential difference may occur between the low potential power line and the data line, between the low potential power line and the high potential power line, and between the data line and the high potential power line. Therefore, there may be a problem in that a parasitic capacitance is generated between the low potential power line, the data line, and the high potential power line and a short defect may occur between the high potential power line, the low potential power line, and the data line by the external environment. Specifically, during the manufacturing process of a display device, a rear surface of the second substrate is in contact with a support unit which supports the second substrate. At this time, a dent may be generated in the rear surface of the second substrate by the contact with the support unit. Specifically, when an optical film is bonded onto the first substrate, a pressure is applied from an upper portion of the first substrate to a bottom portion of the second substrate, which may cause damages, such as dent or scratches, on the rear surface of the second substrate, due to the pressure. Therefore, a short-circuit path may be formed between the low potential power line and the data line and between the low potential power lines, due to the external impact.

Accordingly, in the display device 100 according to the exemplary embodiment of the present disclosure, a transparent conductive layer disposed on the rear surface of the second substrate 130 may be formed with the same mask as the metal layer. For example, the third bottom pad electrode BPEc which is disposed on the lowest portion of the plurality of pad electrodes which configures the plurality of bottom pads BPAD and is formed of the transparent conductive layer may be formed by the same process as the second bottom pad electrode BPEb which is formed of a metal layer. Therefore, mask processes may be reduced. Further, the plurality of wiring lines disposed on the same layer as the third bottom pad electrodes BPEc may be formed using the same mask as the plurality of wiring lines disposed on the same layer as the second bottom pad electrode BPEb. For example, the second bottom data link line BDLb disposed on the same layer as the third bottom pad electrode BPEc may be formed by the same process as the first bottom data link line BDLa disposed on the same layer as the second bottom pad electrode BPEb. Further, the second bottom auxiliary high potential power line BAVL1b disposed on the same layer as the third bottom pad electrode BPEc may be formed by the same process as the first bottom auxiliary high potential power line BAVL1a disposed on the same layer as the second bottom pad electrode BPEb. Therefore, the number of masks may be reduced and the manufacturing cost and the manufacturing time may be reduced.

Further, in the display device 100 according to the exemplary embodiment of the present disclosure, the transparent conductive layer disposed on the rear surface of the second substrate 130 is formed by the same mask as the metal layer so that only the second insulating layer 132 may be disposed below the bottom data link line BDL. For example, the bottom data link line BDL may include a first bottom data link line BDLa formed of a metal layer and a second bottom data link line BDLb formed of a transparent conductive layer. Therefore, the second bottom data link line BDLb having the same potential as the first bottom data link line BDLa is disposed below the first bottom data link line BDLa. Therefore, when a damage, such as dent or scratches occurs on the rear surface of the second substrate 130, short defects may not be caused between wiring lines having different loads. Therefore, the short-circuit path which may be generated on the rear surface of the second substrate 130 is reduced to improve the reliability of the display device 100.

The exemplary embodiments of the present disclosure can also be described as follows:

According to an aspect of the present disclosure, there is provided a display device. The display device comprises a first substrate including a plurality of top pads; a second substrate including a plurality of bottom pads; and a plurality of side lines which connects the plurality of top pads and the plurality of bottom pads, wherein each of the plurality of bottom pads includes a first bottom pad electrode disposed below the second substrate; a first insulating layer disposed below the first bottom pad electrode; a second bottom pad electrode disposed below the first insulating layer; a third bottom pad electrode disposed below the second bottom pad electrode; and a second insulating layer disposed below the third bottom pad electrode, and the third bottom pad electrode is formed of a transparent conductive material.

The third bottom pad electrode and the second bottom pad electrode may completely overlap.

The first insulating layer and the second insulating layer may be inorganic insulating layers and the second insulating layer may open a portion of the third bottom pad electrode.

The third bottom pad electrode may be in contact with the plurality of side lines.

The second substrate may include a plurality of first bottom pads disposed in a first edge of the second substrate; and a plurality of second bottom pads disposed in a second edge of the second substrate, a high potential power voltage may be applied to the plurality of first bottom pads, and a low potential power voltage may be applied to the plurality of second bottom pads.

The plurality of top pads may include a plurality of first top pads and a plurality of second top pads, the plurality of side lines may include a plurality of first side lines which connects the plurality of first top pads and the plurality of first bottom pads; and a plurality of second side lines which connects the plurality of second top pads and the plurality of second bottom pads.

The display device may further comprise a low potential power line, a high potential power line, and a plurality of data lines disposed on the second substrate, wherein the plurality of data lines may overlap a portion of the high potential power line.

The display device may further comprise a plurality of flexible films disposed between the high potential power line and the low potential power line; and a plurality of auxiliary high potential power lines which may be disposed above the high potential power line to be in contact with the high potential power line, wherein each of the plurality of auxiliary high potential power lines may be disposed alternately with each of the plurality of flexible films.

The high potential power line may be formed of a same material as the first bottom pad electrode and the plurality of auxiliary high potential power lines may be formed of a same material as the second bottom pad electrode and the third bottom pad electrode.

A width of each of the plurality of auxiliary high potential power lines may increase as it is adjacent to the low potential power lines.

The display device may further comprise a plurality of COF pads which may be disposed on the second substrate and may be attached with the flexible film, wherein each of the plurality of COF pads may include a first COF pad electrode, a second COF pad electrode, and a third COF pad electrode which may be formed of a same material as the first bottom pad electrode, the second bottom pad electrode, and the third bottom pad electrode, respectively, and the second COF pad electrode and the third COF pad electrode may completely overlap.

The second substrate may include a plurality of first bottom pads disposed in a first edge of the second substrate; and a plurality of second bottom pads disposed in a second edge of the second substrate, the high potential power line may be disposed in the first edge of the second substrate to be connected to the plurality of first bottom pads, and the low potential power line may be disposed in the second edge of the second substrate to be connected to the plurality of second bottom pads.

A width of the high potential power line may correspond to a distance between outermost first bottom pads among the plurality of first bottom pads, and a width of the low potential power line may correspond to a distance between outermost second bottom pads among the plurality of second bottom pads.

The low potential power line may be formed of a same material as the first bottom pad electrode, the second bottom pad electrode, and the third bottom pad electrode.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalent.

What is claimed is:

1. A display device, comprising:
a first substrate including a plurality of top pads;
a second substrate including a plurality of bottom pads; and
a plurality of side lines which connects the plurality of top pads and the plurality of bottom pads,
wherein each of the plurality of bottom pads includes:
a first bottom pad electrode disposed below the second substrate;
a first insulating layer disposed below the first bottom pad electrode;
a second bottom pad electrode disposed below the first insulating layer;
a third bottom pad electrode disposed below the second bottom pad electrode; and
a second insulating layer disposed below the third bottom pad electrode, and
the third bottom pad electrode is formed of a transparent conductive material.

2. The display device according to claim 1, wherein the third bottom pad electrode and the second bottom pad electrode completely overlap.

3. The display device according to claim 1, wherein the first insulating layer and the second insulating layer are inorganic insulating layers and the second insulating layer opens a portion of the third bottom pad electrode.

4. The display device according to claim 3, wherein the third bottom pad electrode is in contact with the plurality of side lines.

5. The display device according to claim 1, wherein the plurality of bottom pads includes:
a plurality of first bottom pads disposed in a first edge of the second substrate; and
a plurality of second bottom pads disposed in a second edge of the second substrate,
a high potential power voltage is applied to the plurality of first bottom pads, and a low potential power voltage is applied to the plurality of second bottom pads.

6. The display device according to claim 5, wherein the plurality of top pads includes a plurality of first top pads and a plurality of second top pads,
the plurality of side lines includes:
a plurality of first side lines which connects the plurality of first top pads and the plurality of first bottom pads; and
a plurality of second side lines which connects the plurality of second top pads and the plurality of second bottom pads.

7. The display device according to claim 1, further comprising:
a low potential power line, a high potential power line, and a plurality of data lines disposed on the second substrate,
wherein the plurality of data lines overlaps a portion of the high potential power line.

8. The display device according to claim 7, further comprising:
a plurality of flexible films disposed between the high potential power line and the low potential power line; and
a plurality of auxiliary high potential power lines which is disposed above the high potential power line to be in contact with the high potential power line,
wherein each of the plurality of auxiliary high potential power lines is disposed alternately with each of the plurality of flexible films.

9. The display device according to claim 8, wherein the high potential power line is formed of a same material as the first bottom pad electrode and the plurality of auxiliary high potential power lines is formed of a same material as the second bottom pad electrode and the third bottom pad electrode.

10. The display device according to claim 8, wherein a width of each of the plurality of auxiliary high potential power lines increase as it is adjacent to the low potential power lines.

11. The display device according to claim 8, further comprising:
a plurality of COF pads which is disposed on the second substrate and is attached with the flexible film,
wherein each of the plurality of COF pads includes:
a first COF pad electrode, a second COF pad electrode, and a third COF pad electrode which are formed of a same material as the first bottom pad electrode, the second bottom pad electrode, and the third bottom pad electrode, respectively, and
the second COF pad electrode and the third COF pad electrode completely overlap.

12. The display device according to claim 7, wherein the plurality of bottom pads includes:
a plurality of first bottom pads disposed in a first edge of the second substrate; and
a plurality of second bottom pads disposed in a second edge of the second substrate,
the high potential power line is disposed in the first edge of the second substrate to be connected to the plurality of first bottom pads, and the low potential power line is disposed in the second edge of the second substrate to be connected to the plurality of second bottom pads.

13. The display device according to claim 12, wherein a width of the high potential power line corresponds to a distance between outermost first bottom pads among the plurality of first bottom pads, and
a width of the low potential power line corresponds to a distance between outermost second bottom pads among the plurality of second bottom pads.

14. The display device according to claim 13, wherein the low potential power line is formed of a same material as the first bottom pad electrode, the second bottom pad electrode, and the third bottom pad electrode.

15. A display device, comprising:
a first substrate including a plurality of top pads;
a second substrate including a plurality of bottom pads;
a plurality of side lines which connects the plurality of top pads and the plurality of bottom pads
a plurality of flexible films and
a plurality of COF pads which is disposed on the second substrate and is attached with the flexible film,
wherein each of the plurality of COF pads includes: a first COF pad electrode, a second COF pad electrode and a third COF pad electrode, and
wherein the first COF pad electrode is disposed below the second substrate, the second COF pad electrode is disposed below the first COF pad electrode, and the third COF pad electrode is disposed below the second COF pad electrode.

16. The display device according to claim 15, wherein the second COF pad electrode and the third COF pad electrode completely overlap.

17. The display device according to claim 15, wherein the third COF pad electrode is formed of a transparent conductive material.
